(19) United States
(12) Patent Application Publication
(10) Pub. No.: US 2010/0096362 A1
(43) Pub. Date: Apr. 22, 2010

(54) PLASMA PROCESSING APPARATUS, POWER SUPPLY APPARATUS AND METHOD FOR OPERATING PLASMA PROCESSING APPARATUS

(75) Inventors: Masaki Hirayama, Miyagi (JP); Tadahiro Ohmi, Miyagi (JP)

Correspondence Address: PEARNE & GORDON LLP, 1801 EAST 9TH STREET, SUITE 1200, CLEVELAND, OH, 44114-3108, US

(73) Assignees: TOKYO ELECTRON LIMITED, Tokyo (JP); TOHOKU UNIVERSITY, Sendai-shi, Miyagi (JP)

(21) Appl. No.: 12/530,923

(22) PCT Filed: Jun. 11, 2008
(86) PCT No.: PCT/JP2008/060672

§ 371 Date: Oct. 12, 2009

(30) Foreign Application Priority Data
Jun. 11, 2007 (JP) 2007-153543

(51) Int. Cl. C23F 1/00; C23F 1/08; C23C 16/00; C23C 16/511; B08B 7/00

(52) U.S. Cl. 216/69; 156/345.41; 118/723 MW; 427/575; 134/1.1

(57) ABSTRACT

In a plasma processing apparatus 10, a microwave transmitted from a microwave source 900 to a coaxial waveguide 600 via a branch waveguide 905 is split into a plurality of microwaves by a branch plate 610 and then transmitted to each internal conductor 315a of a plurality of coaxial waveguides. The microwave transmitted through each internal conductor 315a of the coaxial waveguides is emitted into a processing chamber 100 from each dielectric plate 305 connected with each internal conductor 315a. A desired plasma processing is performed on a substrate G by exciting a processing gas introduced into the processing chamber 100 by the emitted microwave. Expandability for the scale-up is improved by using the plurality of dielectric plates 305. It is possible to design a compact transmission line and supply a low frequency microwave by using the coaxial waveguide in the transmission line.

### TECHNICAL FIELD

The present disclosure relates to a plasma processing apparatus configured to perform a plasma processing on a target object by exciting a gas by using an electromagnetic wave; and more particularly to an electromagnetic wave transmission line using a coaxial waveguide.

### BACKGROUND ART

Conventionally, a waveguide or a coaxial waveguide has been used as a transmission line for supplying an electromagnetic wave to a plasma processing apparatus (see, for example, Patent Document 1). In Patent Document 1, a microwave transmitted through a coaxial waveguide passes through a line-shaped slot formed in a radial line slot antenna, and the microwave passes through a large-sized dielectric plate and then is supplied into a processing chamber.

If an electron density nₑ of plasma is higher than a cut-off density n_{c} (to be exact, a surface wave resonance density nₛ), the microwave supplied into the processing chamber can not be penetrated into the plasma and becomes a surface wave and propagates between the dielectric plate and the plasma.

Generally, a surface wave is expressed as a combination of multi-modes. Meanwhile, a plasma density varies depending on a surface wave mode. Therefore, the surface wave of a multi-mode may generate non-uniform plasma which is not suitable for the processing.

If the microwave is transmitted through the large-sized dielectric plate, a mode of the microwave propagating the dielectric plate can not be controlled and becomes a multi-mode. Recently, as a target object is getting large-sized, a dielectric plate is gradually getting large-sized, so that the surface wave of the microwave passing through the dielectric plate has a multi-mode, thereby increasing the possibility of generation of non-uniform plasma.

For this reason, there is considered a method for generating uniform plasma. According to the method, the dielectric plate is divided into a plurality of dielectric plates to allow each dielectric plate to have a small size, so that the number of propagation modes of the microwave decreases when the microwave passes through each dielectric plate, and thus the plasma is uniformly generated.

In this case, in order to transmit the microwave to the plurality of dielectric plates, the transmission line has to be multi-branched. As an example, there is a method in which a waveguide is branched, so that the microwave is split and transmitted (see, for example, Patent Documents 2 and 3).

Patent Document 1: Japanese Patent Laid-Open Application No. H11-297672

Patent Document 2: Japanese Patent Laid-Open Application No. 2004-200646

Patent Document 3: Japanese Patent Laid-Open Application No. 2005-268653

### DISCLOSURE OF THE INVENTION

### Problems to be Solved by the Invention

However, if a multi-branched transmission line installed at an upper part of a processing chamber is complicated and large-sized, it becomes an obstacle to a maintenance operation. In particular, if a frequency of a microwave is set to be smaller than about 2.45 GHz, a cut-off density n_{c} which is proportional to a square of the frequency of the microwave may be sharply reduced, but a wavelength of the microwave becomes long. Therefore, a size of a waveguide becomes large.

For example, if a frequency of the microwave is about 915 MHz, the employed waveguide has a cross-sectional area of about 247.7 mm×123.8 mm. This is about five times as large as a cross-sectional area of a waveguide used when a frequency of the microwave is about 2.45 GHz. Accordingly, it is difficult to compactly and integrally install such a large waveguide at an upper part of a small-sized plasma processing apparatus. Therefore, it is necessary to design a compact multi-branched transmission line by using a coaxial waveguide to transmit a low frequency microwave.

### Means for Solving the Problems

In accordance with an aspect of the present invention, there is provided a plasma processing apparatus that performs a plasma processing on a target object by exciting a gas by an electromagnetic wave, the apparatus including: a processing chamber; an electromagnetic wave source configured to output the electromagnetic wave; a transmission line configured to transmit the electromagnetic wave outputted from the electromagnetic wave source; a plurality of dielectric plates installed on an inner wall of the processing chamber and configured to allow the electromagnetic wave to pass therethrough and to be emitted to an inside of the processing chamber; a plurality of conductive rods positioned adjacent to or close to the plurality of dielectric plates and configured to transmit the electromagnetic wave to the plurality of dielectric plates; and a branch unit configured to split the electromagnetic wave transmitted through the transmission line into a plurality of electromagnetic waves and transmit them to the plurality of conductive rods, wherein one or more conductive rods are adjacent to or close to each of the dielectric plates.

With this configuration, the electromagnetic wave transmitted from the electromagnetic wave source to the transmission line is split into the plurality of electromagnetic waves by the branch unit and transmitted to the plurality of conductive rods. One or more conductive rods are adjacent to or close to each of the dielectric plates. Each conductive rod transmits the electromagnetic wave to the dielectric plate adjacent or close thereto, and the electromagnetic wave is supplied into the processing chamber from each dielectric plate.

In this way, by using the conductive rod when transmitting the electromagnetic wave, a low frequency electromagnetic wave can be supplied and a simple and compact transmission line can be designed. As a result, a maintenance operation can be facilitated. Further, the plurality of dielectric plates is used to propagate the electromagnetic waves, so that a propagation mode can be easily controlled in comparison to a case where one sheet of large-sized dielectric plate is used, and thus more uniform plasma can be generated.

The transmission line may include a first coaxial waveguide, and the branch unit may be a branch member configured to connect an internal conductor of the first coaxial waveguide with each of the conductive rods. Further, the transmission line may include a first coaxial waveguide, and the branch unit may be a distribution waveguide into which an internal conductor of the first coaxial waveguide and the plurality of conductive rods are inserted.

In this case, the plurality of conductive rods may be concentrically arranged with respect to a central axis of the internal conductor of the first coaxial waveguide at the same interval while being substantially parallel to each other, or may be arranged in a point symmetry with respect to a central axis of the internal conductor of the first coaxial waveguide while being substantially parallel to each other.

Accordingly, the conductive rods are arranged symmetrically with respect to the internal conductor of the first coaxial waveguide. With this configuration, it is possible to control the phase and the power of the electromagnetic wave which split and transmitted to the plurality of conductive rods through the internal conductor of the first coaxial waveguide.

Further, the branch unit may be installed to be substantially parallel to the plurality of dielectric plates and the branch unit may be an internal conductor of a second coaxial waveguide connecting the transmission line with the plurality of conductive rods. In this case, the transmission line may be a first coaxial waveguide or a waveguide.

Accordingly, by using the internal conductor of the second coaxial waveguide as the branch unit, the electromagnetic wave transmitted through the transmission line can be split and provided to the plurality of conductive rods via the internal conductor of the second coaxial waveguide.

The plurality of conductive rods may be connected to the internal conductor of the second coaxial waveguide at the same interval while being substantially parallel to each other. A pitch between the dielectric plates may be set to be about n₁×λg/2, λg being a waveguide wavelength of the electromagnetic wave transmitted through the second coaxial waveguide and n₁ being an integer equal to or greater than 1.

By setting the pitch between the dielectric plates to be about n₁×λg/2 (λg is a waveguide wavelength of the electromagnetic wave transmitted through the second coaxial waveguide, n₁ is an integer equal to or greater than 1 and n₂ is an integer equal to or greater than 1), the electromagnetic wave split at each branch position can be transmitted while its phase is synchronized and its power is split uniformly.

The plasma processing apparatus may further include: a short-circuit unit configured to short-circuit a cover of the processing chamber and each of the conductive rods, wherein a distance from a position where the branch member is connected with each of the conductive rods to the short-circuit unit is set to be about λg/4, λg being a wavelength of the electromagnetic wave transmitted through each of the conductive rods.

The plasma processing apparatus may further include: a short-circuit unit configured to short-circuit a cover of the processing chamber and each of the conductive rods, wherein a distance from a position where the internal conductor of the second coaxial waveguide is connected with each of the conductive rods to the short-circuit unit is set to be about λg/4, λg being a wavelength of the electromagnetic wave transmitted through each of the conductive rods.

In the same manner, the plasma processing apparatus may further include: a short-circuit unit configured to short-circuit a cover of the processing chamber and each of the conductive rods, wherein an end portion of the cover of the processing chamber includes one of an end portion of the distribution waveguide in a lengthwise direction thereof and end portions formed in an L-shape at both ends of the distribution waveguide; and a distance from each of the conductive rods to the end portion of the cover of the processing chamber is set to be about λg/4, λg being a waveguide wavelength of the electromagnetic wave transmitted through the distribution waveguide.

In the same manner, the plasma processing apparatus may further include: a short-circuit unit configured to short-circuit a cover of the processing chamber and the internal conductor of the second coaxial waveguide, wherein a distance from a position where the internal conductor of the second coaxial waveguide is connected with each of the conductive rods to the short-circuit unit is set to be about λg/4, λg being a waveguide wavelength of the electromagnetic wave transmitted through the second coaxial waveguide.

For example, as illustrated on the left side of FIG. 3, if a peak of the microwave is set on the position Dp, power of the microwave at the short-circuit unit 520 is 0. A line between the short-circuit unit and the position Dp may be regarded as a distributed parameter line having its one end short-circuited. Impedance of the distributed parameter line having its one end short-circuited and having a length of λg/4 appears substantially infinite if seen from the other end thereof. Therefore, the line from the position Dp to the short-circuit unit can be regarded as non-existent during the transmission of the microwave. Accordingly, it becomes easy to design the transmission line.

A dielectric member for impedance matching may be installed in a branch point of the branch unit. In this way, reflection in the transmission line can be suppressed, so that the microwave can be efficiently transmitted.

The transmission line may include a plurality of first coaxial waveguides, each of the plurality of first coaxial waveguides may be configured to transmit the electromagnetic wave to the plurality of the conductive rods via the branch unit, the transmission line may further include at least one third coaxial waveguide positioned substantially parallel to the plurality of dielectric plates, and internal conductors of the plurality of first coaxial waveguides may be connected with an internal conductor of the third coaxial waveguide.

The internal conductors of the plurality of first coaxial waveguides connected with the internal conductor of the third coaxial waveguide may be arranged at an interval of about n₂×λg/2, λg being a waveguide wavelength of the electromagnetic wave transmitted through the third coaxial waveguide and n₂ being an integer equal to or greater than 1.

The transmission line may include a plurality of the third coaxial waveguides and further include a plurality of fourth coaxial waveguides, each internal conductor of the fourth coaxial waveguides may be connected with each internal conductor of the third coaxial waveguides, and the internal conductors of the plurality of fourth coaxial waveguides may be positioned above the internal conductors of the plurality of the first coaxial waveguides, and arranged at an interval of about n₂×λg/2, n₂ being an integer equal to or greater than 1.

With this configuration, the first to fourth coaxial waveguides can be connected and branched in multiple levels with a predetermined regularity. Accordingly, the electromagnetic wave can be transmitted while its phase is synchronized and its power is split uniformly at each branch point.

It is desirable that n₁ and n₂ is 1 or 2. The reason for this is that if the value of n₁ or n₂ becomes larger, the travelling distance of the electromagnetic wave becomes long, so that the synchronization of phases and the distribution of power become non-uniform, and thus it becomes difficult to uniformly split and transmit the electromagnetic wave. Further, the reason for this is that if the value of n₁ or n₂ becomes larger, the transmission line becomes complicated and larger, so that it becomes difficult to perform the maintenance operation. If the value of n₁ or n₂ is 1, the distance between the internal conductors of the second coaxial waveguides is about λg/2. In this case, it is better to supply a low frequency electromagnetic wave than a high frequency electromagnetic wave. If the high frequency electromagnetic wave is supplied, the waveguide wavelength λg of the electromagnetic wave becomes short, so that the distance between the internal conductors of the second coaxial waveguides becomes short. Therefore, the number of the dielectric plates increases, and thus the cost increases.

The electromagnetic wave source may be connected with a branch waveguide having a tournament structure in which a two-branch is repeated one time or more. A branch point of the branch waveguide may have a T-branch or a Y-branch structure.

With this configuration, at each branch end point of the branch waveguide having a multi-branched tournament structure, there can be connected each internal conductor of the plurality of coaxial waveguides or a certain waveguide. Further, in this way, the distance from an entrance of the branch waveguide to each branch end point can be the same. Accordingly, the electromagnetic wave can be transmitted while its phase is synchronized and its power is split uniformly.

A coolant flow path may be installed within the internal conductor of the second coaxial waveguide. Further, a coolant flow path may be installed within the internal conductor of the third coaxial waveguide.

The internal conductor of the second or third coaxial waveguide may have a double structure made up of an outer pipe and an inner pipe.

Further, the internal conductor of the second or third coaxial waveguide may be divided into two or more internal conductors, and the divided two or more internal conductors of the second or third coaxial waveguide may be connected with each other by a connector. Further, the connector may be installed at the outer pipe. With this configuration, the connector electrically connects the pipes with each other, and the connector absorbs thermal expansion or thermal contraction to prevent stress caused by the thermal expansion or the thermal contraction from being applied to the pipes.

Further, since the pipe is formed in a double structure and the connector is installed, the outer pipe can slide in a horizontal direction without exerting an influence upon the internal pipe. Accordingly, the warp of the transmission line caused by the thermal expansion or the thermal contraction can be absorbed by the connector with less stress.

In this case, by allowing the coolant to flow in the internal pipe, the internal conductor (pipe) can be efficiently cooled by heat conduction. Further, by installing a holding unit that holds the second or third coaxial waveguide at the vicinity of the connector, the internal pipe can be positioned in the center of the outer pipe.

The plurality of conductive rods may be slidably engaged with the internal conductor of the second coaxial waveguide at a connection point therebetween in a lengthwise direction of the second coaxial waveguide. Further, the plurality of conductive rods may be slidably engaged with the cover of the processing chamber at the short-circuit unit. Accordingly, the conductive rods or the internal conductors slide due to a stress caused by the heat, so that it is possible to prevent stress from being applied to the transmission line.

The electromagnetic wave source may output an electromagnetic wave having a frequency of about 1 GHz or less. In this way, a cut-off density can be reduced. Accordingly, a process window can be enlarged and thus various processes can be implemented by one apparatus.

In accordance with another aspect of the present invention, there is provided a power supply apparatus capable of supplying an electromagnetic wave having a frequency of about 1 GHz or less to a plasma processing apparatus, the power supply apparatus including: an electromagnetic wave source configured to output the electromagnetic wave; a transmission line configured to transmit the electromagnetic wave outputted from the electromagnetic wave source; a plurality of conductive rods, positioned adjacent to or close to a plurality of dielectric plates installed on an inner wall of the processing chamber, configured to transmit the electromagnetic wave to the plurality of dielectric plates; and a branch unit configured to split the electromagnetic wave transmitted through the transmission line into a plurality of electromagnetic waves and transmit them to the plurality of the conductive rods, wherein one or more conductive rods are adjacent to or close to each of the dielectric plates.

With this configuration, a coaxial waveguide having a size independent of the wavelength of the electromagnetic wave is used in the transmission line when the electromagnetic wave having a frequency of about 1 GHz or less is supplied. Therefore, it is possible to supply a low frequency electromagnetic wave and prevent the scale-up of the transmission line required for supplying the low frequency microwave. Accordingly, a simple and compact transmission line can be designed.

Further, in accordance with still another aspect of the present invention, there is provided a method for operating a plasma processing apparatus, the method including: outputting an electromagnetic wave having a frequency of about 1 GHz or less from an electromagnetic wave source; transmitting the electromagnetic wave outputted from the electromagnetic wave source to a transmission line; splitting the electromagnetic wave transmitted through the transmission line into a plurality of electromagnetic waves and transmitting them to a plurality of conductive rods; emitting the electromagnetic wave into the processing chamber from one or more conductive rods adjacent to or close to each of dielectric plates via each of the dielectric plates; and performing a desired plasma processing on a target object by exciting a processing gas introduced into the processing chamber by the emitted electromagnetic wave.

Further, in accordance with still another aspect of the present invention, there is provided a method for cleaning a plasma processing apparatus, the method including: outputting an electromagnetic wave having a frequency of about 1 GHz or less from an electromagnetic wave source; transmitting the electromagnetic wave outputted from the electromagnetic wave source to a transmission line; splitting the electromagnetic wave transmitted through the transmission line into a plurality of electromagnetic waves and transmitting them to a plurality of conductive rods; emitting the electromagnetic wave into the processing chamber from one or more conductive rods adjacent to or close to each of dielectric plates via each of the dielectric plates; and cleaning the plasma processing apparatus by exciting a cleaning gas introduced into the processing chamber by the emitted electromagnetic wave.

With this method, by supplying the electromagnetic wave having the frequency of about 1 GHz or less to the plasma processing apparatus, the cut-off density n_{c} which is proportional to the square of the frequency of the electromagnetic wave can be sharply reduced. Accordingly, a process window can be enlarged and thus various processes can be implemented by one apparatus.

For example, a F-based single gas could not excite uniform and stable plasma by using the electromagnetic wave having a frequency of about 2.45 GHz because it does not spread as a surface wave in a single gas state with a certain level of power. However, the F-based single gas can excite the uniform and stable plasma if the electromagnetic wave having a frequency of about 1 GHz or less is used. Accordingly, the cleaning gas can be excited by the practical power of the electromagnetic wave, and thus the inside of the plasma processing apparatus can be cleaned by the generated plasma.

### BRIEF DESCRIPTION OF THE DRAWINGS

FIG. 1 is a longitudinal cross-sectional view taken along plane X-Z of a plasma processing apparatus in accordance with a first embodiment of the present invention;

FIG. 2 is a view illustrating a ceiling surface of the plasma processing apparatus in accordance with the embodiment;

FIG. 3 is an enlarged cross-sectional view of the vicinity of a branch plate in accordance with the embodiment;

FIG. 4 is a view illustrating an upper part of a longitudinal cross-sectional view taken along plane Y-Z of the plasma processing apparatus in accordance with the embodiment;

FIG. 5 is an enlarged cross-sectional view of a branch coaxial waveguide in accordance with the embodiment;

FIG. 6 is a view for describing a waveguide having a tournament structure in accordance with the embodiment;

FIG. 7 is a cross-sectional view taken along line C-C of FIG. 3;

FIG. 8 is a longitudinal cross-sectional view of a plasma processing apparatus in accordance with a second embodiment of the present invention;

FIG. 9 is a cross-sectional view taken along line X-X of FIG. 8;

FIG. 10 is a cross-sectional view taken along line F-F of FIG. 8;

FIG. 11 is a longitudinal cross-sectional view of a plasma processing apparatus in accordance with a modification example of the second embodiment of the present invention;

FIG. 12 is a cross-sectional view taken along line G-G of FIG. 11;

FIG. 13 is a longitudinal cross-sectional view of a plasma processing apparatus in accordance with a third embodiment of the present invention;

FIG. 14 is a cross-sectional view taken along line P-P of FIG. 13;

FIG. 15 is a cross-sectional view taken along line U-U of FIG. 13;

FIG. 16 is a longitudinal cross-sectional view of a plasma processing apparatus in accordance with a modification example of the third embodiment;

FIG. 17 is a longitudinal cross-sectional view of a plasma processing apparatus in accordance with a modification example of the third embodiment;

FIG. 18 provides an enlarged view and a cross-sectional view of a part of a branch coaxial waveguide;

FIG. 19 is a longitudinal cross-sectional view of a plasma processing apparatus in accordance with a fourth embodiment of the present invention;

FIG. 20 is a cross-sectional view taken along line V-V of FIG. 19;

FIG. 21 is a cross-sectional view taken along line W-W of FIG. 19;

FIG. 22 is a longitudinal cross-sectional view of a plasma processing apparatus in accordance with a modification example;

FIG. 23 is a cross-sectional view taken along line Z-Z of FIG. 22;

FIG. 24 is a graph illustrating a relationship between a power density of a microwave and an electron density of plasma;

FIG. 25 is a view illustrating a modification example of a branch waveguide; and

FIG. 26 is a cross-sectional view taken along line 1-1 of FIG. 25.

### EXPLANATION OF CODES

10: Plasma processing apparatus
100: Processing chamber
200: Chamber main body
205, 415a, 415b, 530: O-ring
300: Cover body
300d: Cover portion
305: Dielectric plate
315: Coaxial waveguide
315a: Internal conductor
410, 615, 630: Dielectric member
500: Fixing mechanism
520, 640: Short-circuit unit
525: Ring-shaped dielectric member
535: Cushion ring
600, 620: Coaxial waveguide
600a, 620a, 670a: Internal conductor
605: Coaxial waveguide converter
635: Fixing device
670: Branch coaxial waveguide
610: Branch plate
645, 665: Connector
900: Microwave source
905: Branch waveguide
910: Distribution waveguide
U: Processing space

### BEST MODE FOR CARRYING OUT THE INVENTION

### First Embodiment

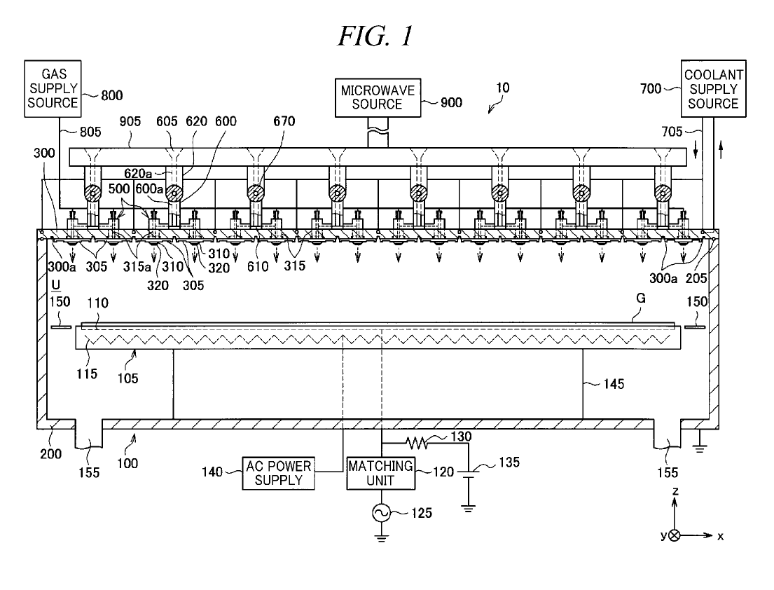

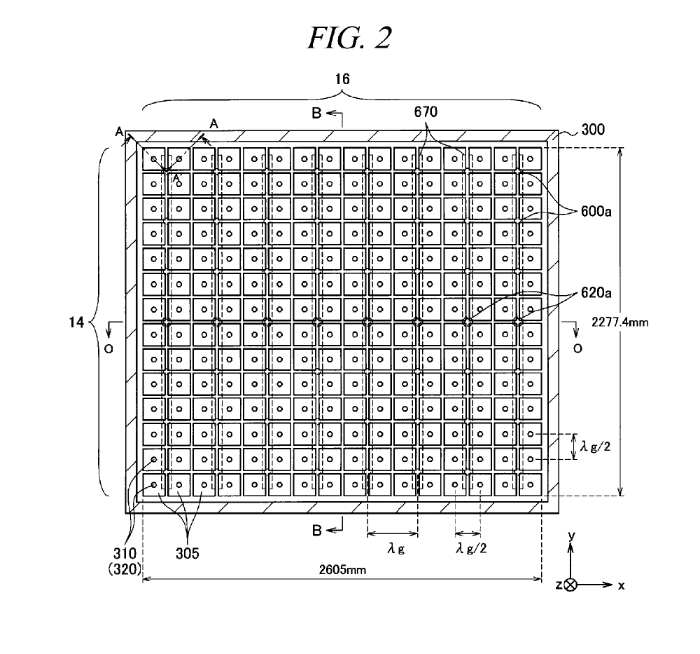

Hereinafter, a plasma processing apparatus in accordance with a first embodiment of the present invention will be described with reference to FIGS. 1 and 2. FIG. 1 is a schematic view (a cross-sectional view taken along line O-O of FIG. 2) showing a longitudinal cross-section of the apparatus, and FIG. 2 is a view illustrating a ceiling surface of a processing chamber. Further, parts having the same configurations and functions will be assigned like reference numerals in the following description and the accompanying drawings, and redundant description thereof will be omitted.

(Configuration of Plasma Processing Apparatus)

A plasma processing apparatus 10 includes a processing chamber 100 configured to perform therein a plasma processing on a glass substrate (hereinafter, referred to as “substrate G”). The processing chamber 100 is made up of a chamber main body 200 and a cover body 300. The chamber main body 200 has a cube shape having a bottom surface and an upper opening, and the opening is closed by the cover body 300. An O-ring 205 is installed at a contact surface between the chamber main body 200 and the cover body 300, so that the chamber main body 200 and the cover body 300 are hermetically sealed, thereby forming a processing space U. The chamber main body 200 and the cover body 300 are made of metal such as aluminum and electrically grounded.

Installed within the processing chamber 100 is a susceptor (stage) 105 configured to mount the substrate G. The susceptor 105 is made of, e.g., aluminum nitride, and a power supply unit 110 and a heater 115 are installed therein.

The power supply unit 110 is connected with a high frequency power supply 125 via a matching unit 120 (for example, a capacitor). Further, the power supply unit 110 is connected with a high voltage DC power supply 135 via a coil 130. The matching unit 120, the high frequency power supply 125, the coil 130 and the high voltage DC power supply 135 are installed outside the processing chamber 100. Furthermore, the high frequency power supply 125 and the high voltage DC power supply 135 are grounded.

The power supply unit 110 is configured to apply a predetermined bias voltage to the inside of the processing chamber 100 by high frequency power outputted from the high frequency power supply 125. Moreover, the power supply unit 110 is configured to electrostatically attract the substrate G by a DC voltage outputted from the high voltage DC power supply 135.

The heater 115 is connected with an AC power supply 140 installed outside the processing chamber 100 and configured to maintain the substrate G at a predetermined temperature by an AC voltage outputted from the AC power supply 140. The susceptor 105 is supported by a supporting body 145 and surrounded by a baffle plate 150 configured to control a gas flow in the processing space U to be a desirable state.

A gas exhaust line 155 is installed at a bottom portion of the processing chamber 100. A gas in the processing chamber 100 is exhausted through the gas exhaust line 155 by a vacuum pump (not illustrated) installed outside the processing chamber 100, so that the processing space U can be depressurized to a desired vacuum level.

A plurality of dielectric plates 305, a plurality of metal electrodes 310 and a plurality of internal conductors 315a of coaxial waveguides are installed at the cover body 300. Referring to FIG. 2, each dielectric plate 305 is made of alumina (Al₂O₃) and is a plate of a substantially square shape having a size of 148 mm×148 mm. The dielectric plates 305 are arranged in column-wise and row-wise at the same interval of an integer multiple of λg/2 (here, integer is 1) when a wavelength in a branch coaxial waveguide 670 is set to be λg (about 328 mm at a frequency of about 915 MHz). Accordingly, 224 (=14×16) sheets of the dielectric plates 305 are arranged uniformly on a ceiling surface of the processing chamber 100 having a size of 2277.4 mm×2605 mm.

As stated above, since the dielectric plate 305 has a good symmetrical shape, it becomes easy to generate uniform plasma at one sheet of the dielectric plate 305. Further, since the plurality of dielectric plates 305 is arranged at the same interval of the integer multiple of λg/2, it is possible to generate uniform plasma when a microwave is introduced by using the internal conductors 315a of the coaxial waveguides.

Referring back to FIG. 1, grooves 300a shown in FIG. 1 are formed in a metal surface of the cover body 300 and configured to suppress propagation of a conductor surface wave. Here, the conductor surface wave implies a wave propagating between the metal surface and plasma.

At a leading end of the internal conductor 315a passing through the dielectric plate 305, the metal electrode 310 is installed to be exposed toward the substrate G. The dielectric plate 305 is held by the internal conductor 315a and the metal electrode 310. On a metal electrode 310's surface facing the substrate, a dielectric cover 320 is installed to prevent concentration of an electric field.

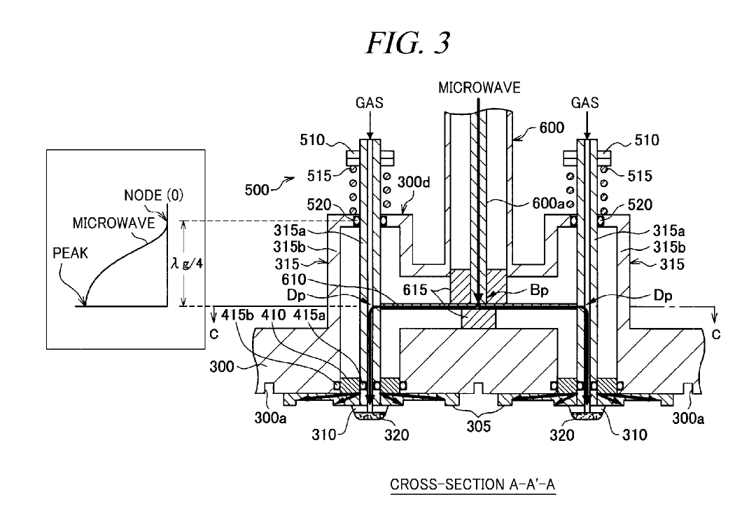

An additional explanation will be made with reference to FIG. 3 showing a cross-sectional view taken along line A-A′-A of FIG. 2. A coaxial waveguide 315 includes an external conductor 315b and the internal conductor (axis part) 315a of a cylinder shape, and is made of metal (desirably, copper). A ring-shaped dielectric member 410 and O-rings 415a and 415b configured to vacuum-seal the processing space U at both sides of the dielectric member 410 are installed between the cover body 300 and the internal conductor 315a.

The internal conductor 315a is configured to pass through a cover portion 300d and protrude outside the processing chamber 100. The internal conductor 315a is lifted up toward the outside of the processing chamber 100 by a fixing mechanism 500 by using elastic force of a spring member 515. The fixing mechanism 500 includes a connecting unit 510, the spring member 515 and a short-circuit unit 520. Further, the cover portion 300d is a portion that is integrated with the cover body 300 and the external conductor 315b at a top surface of the cover body 300.

The short-circuit unit installed at a through portion of the internal conductor 315a is configured to electrically short-circuit the internal conductor 315a of the coaxial waveguide 315 and the cover portion 300d. The short-circuit unit 520 is configured as a shield spiral such that the internal conductor 315a can slide up and down. Further, a metal brush can be used in the short-circuit unit 520.

By installing the short-circuit unit 520 as stated above, heat introduced to the metal electrode 320 from plasma can be transferred efficiently to the cover via the internal conductor 315a and the short-circuit unit. Accordingly, heating of the internal conductor 315a is suppressed, so that the O-rings 415a and 415b adjacent to the internal conductor 315a can be prevented from being deteriorated. Furthermore, since the short-circuit unit 520 prevents the microwave from being transmitted to the spring member 515 through the internal conductor 315a, abnormal electric discharge or power loss does not occur in the vicinity of the spring member 515. Moreover, the short-circuit unit 520 prevents an axis of the internal conductor 315a from being shaken and firmly supports the internal conductor 315a.

Furthermore, O-rings (not illustrated) are installed to vacuum-seal a gap between the cover portion 300d and the internal conductor 315a at the short-circuit unit 520 and a gap between a dielectric member 615 to be described later and the cover portion 300d. Further, a space within the cover portion 300d is filled with a nonreactive gas, so that impurities in an atmosphere can be prevented from being mixed into the processing space.

A coolant supply source 700 of FIG. 1 is connected with a coolant line 705. Coolant supplied from the coolant supply source 700 circulates in the coolant line 705 and returns to the coolant supply source 700, so that the processing chamber 100 can be maintained at a desired temperature.

A gas supply source 800 introduces a gas into the processing space from a gas flow path in the internal conductor 315a illustrated in FIG. 3 via a gas line 805.

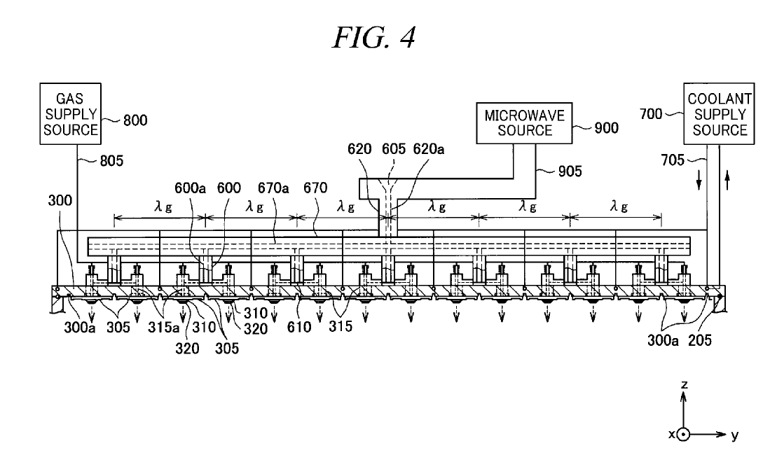

A microwave of 120 kW (=60 kW×2(2 W/cm²)) outputted from two microwave sources 900 is transmitted through a branch waveguide 905, eight coaxial waveguide converters 605, eight coaxial waveguides 620, seven coaxial waveguides 600 connected with each of eight branch coaxial waveguides 670 (see FIGS. 2 and 4) and arranged in parallel to each other in a rear surface direction of FIG. 1, a branch plate 610 and the coaxial waveguide 315. Then, the microwave passes through the plurality of dielectric plates 305 and is supplied into the processing space. The microwave emitted to the processing space U excites a processing gas supplied from the gas supply source 800 into plasma, and by using the generated plasma, a desired plasma processing is performed on the substrate G.

Further, the branch waveguide 905 and the coaxial waveguides 600, 620, 670 and 315 are examples of a transmission line. More particularly, the coaxial waveguide 600 is an example of a first coaxial waveguide and the internal conductor 315a of the coaxial waveguide 315 is an example of a conductive rod. Further, the branch plate 610 is an example of a branch member installed between the first coaxial waveguide and the conductive rod. The branch member may not have a plate shape but may have a rod shape, for example.

<Transmission Line>

In the plasma processing apparatus 10 explained above, the transmission line is designed to allow a microwave having a low frequency of about 1 GHz or less to be supplied to the processing chamber 100 and allow an upper part of the processing chamber 100 to have a simple structure. Hereinafter, the transmission line in accordance with the present embodiment will be explained in detail.

(Branch Coaxial Waveguide)

FIG. 4 is a cross-sectional view (90 degrees different from the cross-sectional view of FIG. 1) taken along line B-B of FIG. 2, and it shows only an upper part of the apparatus. With reference to FIG. 4, the coaxial waveguide 620 is connected with the plurality of coaxial waveguides 600 via the branch coaxial waveguide 670. The branch coaxial waveguide 670 is an example of a second coaxial waveguide (parallel coaxial waveguide) positioned substantially parallel to the plurality of dielectric plates 305, and the coaxial waveguides 600 and 620 are examples of one or more vertical coaxial waveguides arranged substantially perpendicular to the plurality of dielectric plates 305.

An internal conductor 670a of the branch coaxial waveguide 670 is connected with seven internal conductors 600a of the coaxial waveguides 600, and a pitch between the internal conductors 600a is set to be about n₁×λg/2 (here, n₁=2). By setting the pitch between the internal conductors 600a to be about an integer multiple of λg/2 (λg is a waveguide wavelength of the microwave transmitted through the branch coaxial waveguide 670), it is possible to uniformly distribute power to the internal conductors 600a. Further, as illustrated in FIG. 2, a pitch between the branch coaxial waveguides 670 is set to be λg which is the same as the pitch between the coaxial waveguides 600. Accordingly, the dielectric plates 305 connected with the internal conductors 315a via the coaxial waveguides 600 and the branch plates 610 are hung on the entire ceiling surface of the processing chamber 100 in column-wise and row-wise at an interval of λg/2. As a result, the dielectric plate has substantially the same size in column-wise and row-wise and a surface wave propagation mode has a good symmetry, so that it becomes easy to obtain plasma uniformity in the dielectric plate surface.

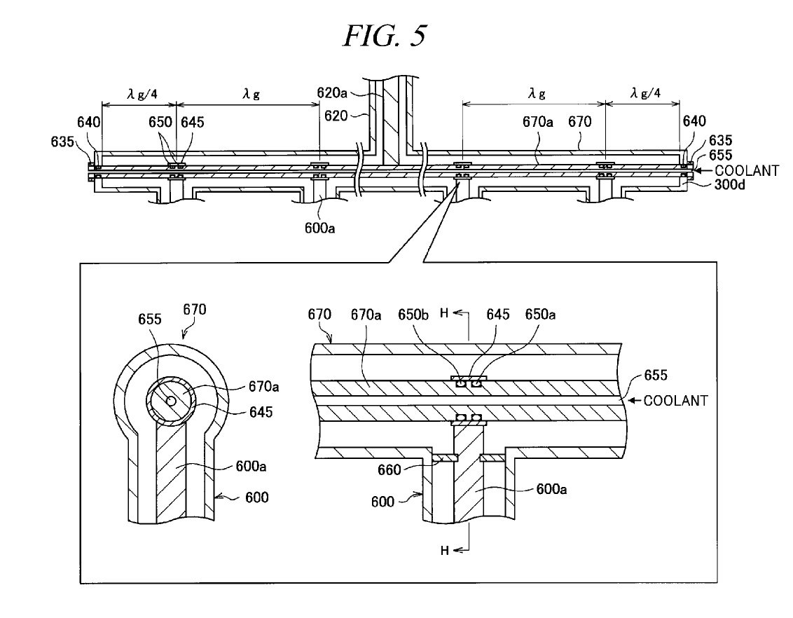

FIG. 5 is an enlarged view of the branch coaxial waveguide 670 of FIG. 4. With reference to FIG. 5, the internal conductor 670a is fixed to an outer frame (cover portion 300d) by fixing devices 635 at both ends thereof, and the fixing devices 635 determines a position of an axial direction of the internal conductor 670a. Further, installed at penetrating portions thereof are short-circuit units 640 that electrically short-circuit the internal conductor 670a of the branch coaxial waveguide 670 and the outer frame (cover portion 300d).

In the lower side of FIG. 5, an enlarged view of a connection point between the internal conductors 670a and 600a is illustrated on the right side thereof and a cross-sectional view taken along line H-H of FIG. 5 is illustrated on the left side thereof. The internal conductor 670a of the branch coaxial waveguide 670 is connected with a cylindrical connector 645. Two shield spirals 650a and 650b are installed on an inner surface of the connector 645, so that the internal conductor 670a can slide in a horizontal direction. Since the internal conductor 670a slides due to a stress caused by the heat, it is possible to prevent stress from being applied to the transmission line.

(Cooling Mechanism)

A path 655 for flowing coolant passes through the inside of the internal conductor 670a. The coolant supplied from the coolant supply source 700 circulates the path 655 connected with the coolant line 705. The cooling mechanism may be installed inside the internal conductor 315a. Accordingly, the internal conductor 670a or the internal conductor 315a can be prevented from being overheated. Further, a holding unit 660 that holds the internal conductor 315a is installed at the internal conductor 315a. The holding unit 660 has a ring shape and is made of Teflon (registered trademark).

(Branch Waveguide)

A magnetron that generates a microwave is generally connected with a waveguide; electric discharge may occur in a coaxial waveguide and the inside thereof may be heated if high power of several tens of kW is outputted directly to the coaxial waveguide from a microwave source; and it becomes difficult to transmit a microwave through a high-power coaxial waveguide having a large diameter in consideration of a transmission mode or a matching if a wavelength of the microwave becomes short. Accordingly, the microwave source is generally connected with the waveguide.

Therefore, in the plasma processing apparatus 10 in accordance with the present embodiment, the branch waveguide 905 is installed at a position on multi-branch lines and the position is adjacent to the microwave source that transmits a high-power microwave.

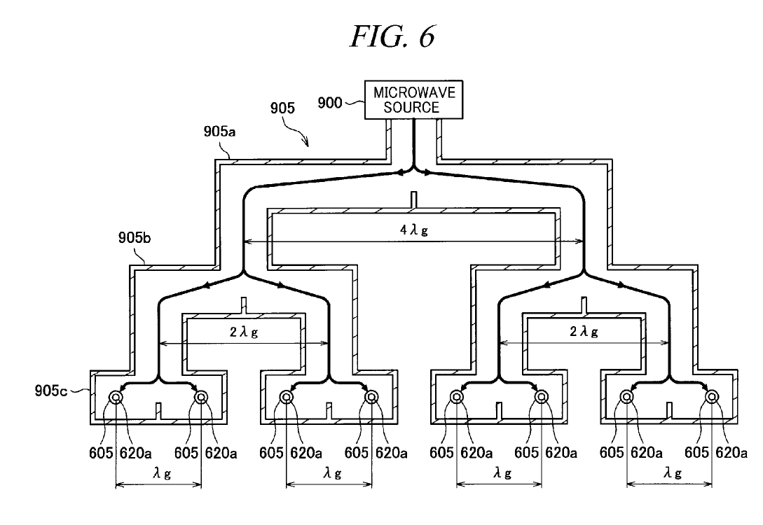

As illustrated in FIG. 6, the branch waveguide 905 has a tournament structure in which a two-branch (T-branch) is repeated one time or more (here, three times). Branch end points of the branch waveguide 905 are connected with the coaxial waveguides 620 via eight coaxial waveguide converters 605. If a wavelength in the branch point of the coaxial waveguide is λg, distances between the waveguides at an upper part 905a, a middle part 905b and a lower part 905c of the branch waveguide 905 are set to be 4 λg (=8×λg/2), 2 λg (=4×λg/2) and λg (=2×λg/2), respectively. That is, the distances are all set to be m×λg/2 (λg is a waveguide wavelength and m is an integer). Meanwhile, as long as the branch waveguide 905 has branch points, it does not have to be branched in a tournament structure.

Accordingly, the travelling distances of the microwave transmitted from the microwave source 900 to the branch end points are the same. As a result, power of the microwave can be split uniformly and provided into eight coaxial waveguides 620 while phases of the split microwave are synchronized.

Further, the branch waveguide 905 may be connected with one of an internal conductor of a parallel coaxial waveguide, an internal conductor of a vertical coaxial waveguide and a certain waveguide.

The coaxial waveguide converter 605 illustrated in FIG. 1 transmits the microwave transmitted through the branch waveguide 905 to the coaxial waveguide 620. The coaxial waveguide 620 is connected with the plurality of coaxial waveguides 600 via the branch coaxial waveguide 670 and further connected with the branch plate 610.

(Branch Plate)

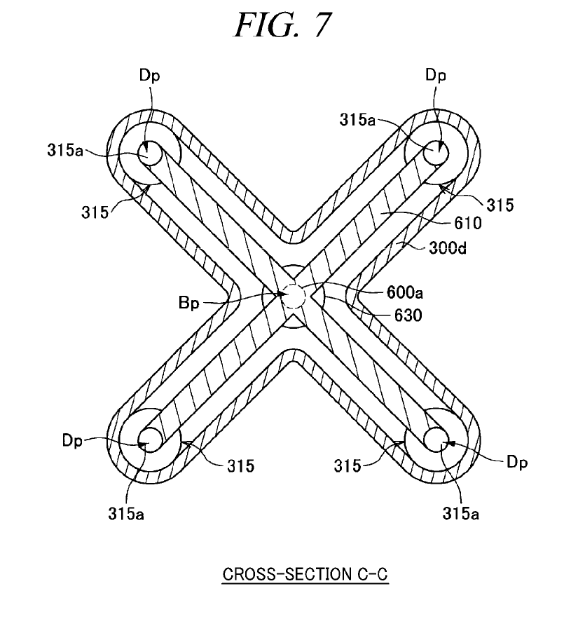

FIG. 7 is a cross-sectional view taken along line C-C of FIG. 3. With reference to FIG. 7, the branch plate 610 has a cross shape of which center is on a connection position Bp with the internal conductor 600a. The branch plate 610 is made of metal such as copper. The branch plate 610 is connected with the internal conductor 315a of the coaxial waveguide 315 at each of four end points (positions Dp).

Further, the branch plate 610 needs to be configured to connect two or more internal conductors 315a, but it does not have to be formed in a cross shape. For example, the branch plate 610 may be configured such that the internal conductors 315a are concentrically arranged with respect to a central axis of the coaxial waveguide 600 at the same interval. Alternatively, it may be configured such that the internal conductors 315a are arranged in point symmetry with respect to a central axis of the coaxial waveguide 600.

(Dielectric Member: Impedance Matching)

The dielectric members 615 made of Teflon (registered trademark) are installed at upper and lower sides of the position Bp of FIG. 3. The dielectric members 615 are installed to support the branch plate 610 and to provide an impedance matching function. With this configuration, a rapid change of impedance at the connection point between the branch plate 610 and the internal conductor 600a can be prevented. As a result, reflection in the transmission line can be suppressed, so that the microwave can be efficiently transmitted.

(Short-Circuit Unit)

A distance from the connection position Dp between the branch plate 610 and the internal conductor 315a to the short-circuit unit 520 is set to be λg/4 (λg is a waveguide wavelength of the microwave). As illustrated on the left side of FIG. 3, if a peak of the microwave is set on the position Dp, power of the microwave at the short-circuit unit 520 is 0. A line between the short-circuit unit 520 and the position Dp may be regarded as a distributed parameter line having its one end short-circuited. Impedance of the distributed parameter line having its one end short-circuited and having a length of λg/4 appears substantially infinite if seen from the other end thereof. Therefore, the line from the position Dp to the short-circuit unit 520 can be regarded as non-existent during the transmission of the microwave. Accordingly, it becomes easy to design the transmission line.

However, the length from the position Dp to the short-circuit unit 520 may be set on a basis of λg/4. That is, the length may be set considering that if the length is shorter than λg/4, it is equivalent to a transmission line having a capacitor (C) component added thereto and if the length is longer than λg/4, it is equivalent to a transmission line having an inductor (L) component added thereto.

The microwave transmitted through the coaxial waveguide 600 is split into a plurality of microwaves by the branch plate 610 and then transmitted to the plurality of internal conductors 315a, and further transmitted to the plurality of dielectric plates 305. Accordingly, the microwave of uniform power is supplied into the processing chamber from 224 sheets of the dielectric plates 305 arranged uniformly on the ceiling surface.

In accordance with the plasma processing apparatus of the present embodiment as described above, it is possible to supply a low frequency microwave and prevent the scale-up of the transmission line required for supplying the low frequency microwave. Accordingly, a simple and compact transmission line can be designed, and maintenance thereof can be facilitated. Further, the microwave is supplied into the processing chamber from the plurality of dielectric plates each having a relatively small size, so that generation of a microwave of a multi-mode can be suppressed and thus uniform plasma can be generated.

### Second Embodiment

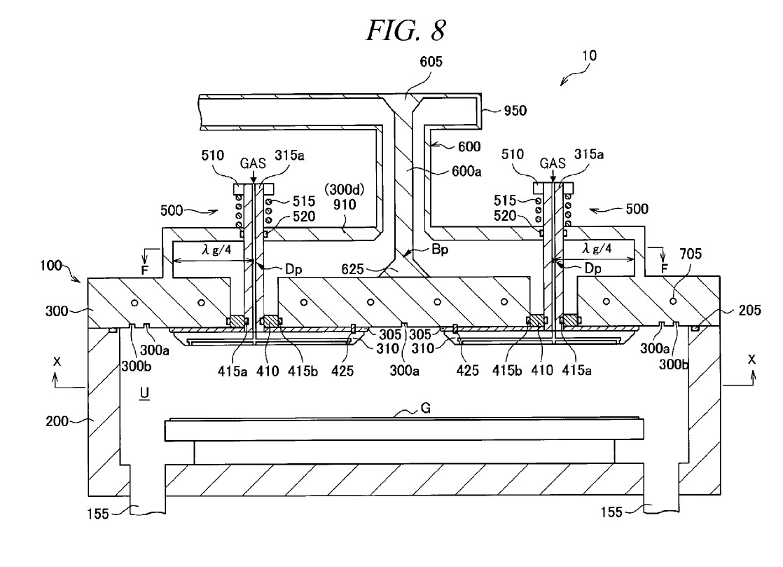

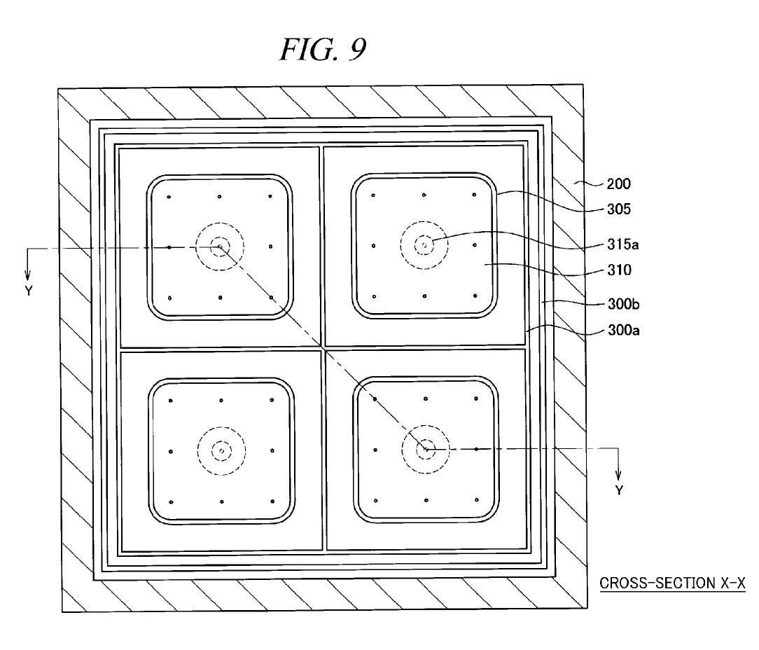

Subsequently, a plasma processing apparatus 10 in accordance with a second embodiment will be explained with reference to FIGS. 8 to 10. FIG. 9 illustrates a cross-sectional view taken along line X-X of FIG. 8. FIG. 8 is a view taken along line Y-Y of FIG. 9. As shown in FIG. 8, the plasma processing apparatus 10 in accordance with the second embodiment is different from the plasma processing apparatus 10 in accordance with the first embodiment in that the former includes a branch unit (distribution waveguide 910) but it does not include a branch coaxial waveguide and a branch waveguide. Accordingly, the distribution waveguide 910 of the plasma processing apparatus 10 in accordance with the second embodiment will be explained hereinafter. The distribution waveguide 910 of the present embodiment is an example of the branch unit.

The distribution waveguide 910 integrated with a cover portion 300d is installed at a top portion of a cover body 300. The distribution waveguide 910 is a hollow waveguide having a shape of a substantially hexahedral structure, and the inside of the distribution waveguide 910 is filled with air. In the present embodiment, four dielectric plates 305 having a substantially square shape are arranged at the same interval as illustrated in FIG. 9.

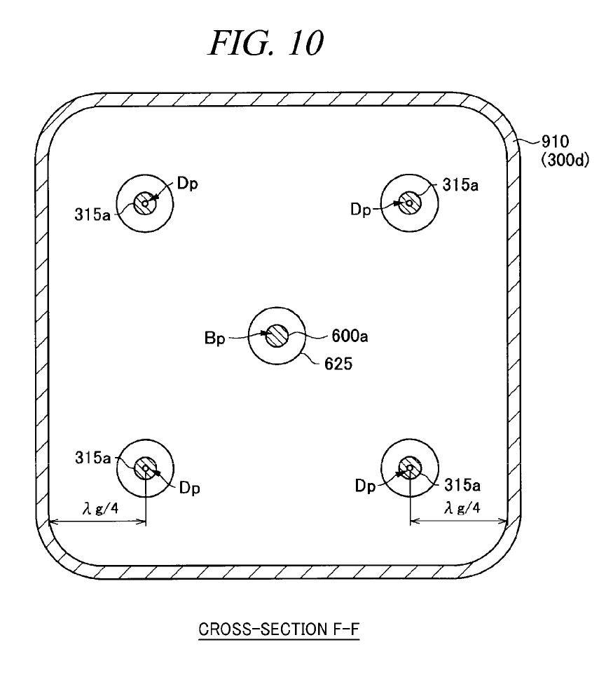

As shown in FIG. 10 which is a cross-sectional view taken along line F-F of FIG. 8, in an inner space of the distribution waveguide 910, an internal conductor 600a of a coaxial waveguide is inserted into the center thereof and four internal conductors 315a are inserted into positions in point symmetry with respect to a central axis of the coaxial waveguide 600. Since electric field strength at an end portion of the distribution waveguide 910 is weak, the microwave is not transmitted to a coaxial waveguide 315 efficiently if the internal conductor 315a is positioned in the vicinity of the end portion thereof. For this reason, a distance between the end portion of the distribution waveguide 910 and the central axis of the internal conductor 315a is set to be about λg/4 if a wavelength in the distribution waveguide 910 is λg, such that the internal conductor 315a is positioned at a position of a peak of an electric field standing wave. Alternatively, the distance may not be about λg/4.

In the plasma processing apparatus in accordance with the present embodiment configured as stated above, the microwave outputted from a microwave source 900 is transmitted from a waveguide 950 (not branched) and the coaxial waveguide 600 to the distribution waveguide 910, and transmitted from the internal conductor 600a to the internal conductor 315a.

Like in FIG. 7, in the present embodiment, four internal conductors 315a are also arranged in point symmetry with respect to the internal conductor 600a. By such symmetry, a phase of the microwave transmitted through the distribution waveguide 910 is synchronized, and the microwave is transmitted to each internal conductor 315a while power of the microwave is split uniformly.

In accordance with the plasma processing apparatus of the second embodiment described above, by using the distribution waveguide 910 as a symmetrical branch (branch unit), the microwave can be transmitted uniformly to the internal conductors 315a from the coaxial waveguide 600 without the branch plate 610.

Further, the plasma processing apparatus 10 in accordance with the second embodiment is different from the plasma processing apparatus 10 in accordance with the first embodiment in that the former has a different shape of the dielectric plate 305 or a metal electrode 310 from that of the latter; the former does not include the dielectric cover 320; the former further has a groove 300b surrounding all the dielectric plates in addition to grooves 300a surrounding each of the dielectric plates 305; and the former has a locking device 425 for preventing the dielectric plate 305 and the metal electrode 310 from being rotated. Likewise, the plasma processing apparatus may be configured to have various shapes of the dielectric plate 305 or the metal electrode 310 or have the dielectric cover 320 included or omitted therein.

In the present embodiment, four sheets of the rectangular dielectric plates are arranged in column-wise and row-wise, but the shape or the arrangement of the dielectric plates is not limited thereto. For example, a plurality of arc-shaped dielectric plates may be arranged in a concentric circular shape or in a ring shape.

### Modification Example of the Second Embodiment

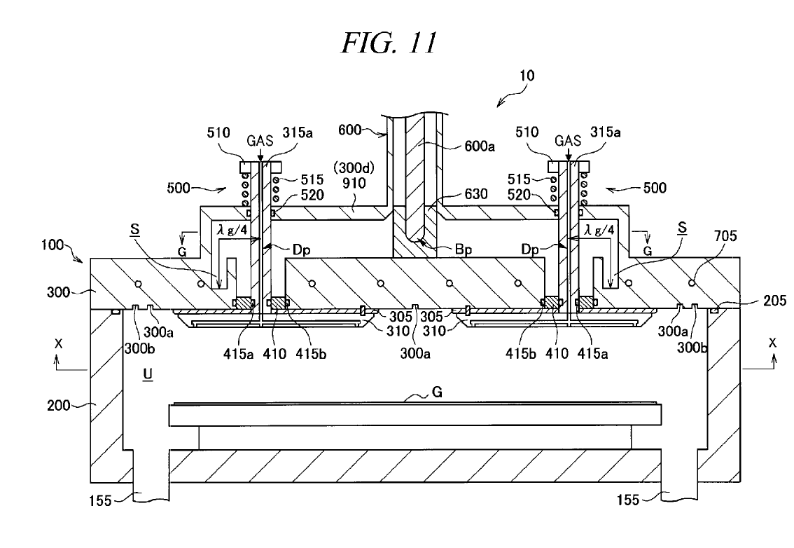

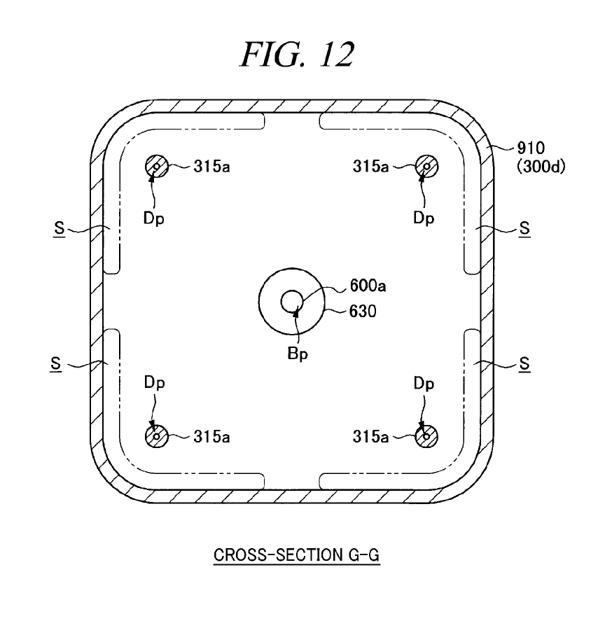

Hereinafter, a plasma processing apparatus 10 in accordance with a modification example of the second embodiment will be explained with reference to FIGS. 11 and 12. The modification example of the second embodiment is different from the second embodiment in that, in the modification example, an internal conductor 600a is not electrically connected with a cover portion 300d in the former; and an end space S of a distribution waveguide 910 is formed by installing a groove in a cover body 300. Therefore, the plasma processing apparatus 10 in accordance with the modification example of the second embodiment will be explained focusing on such differences.

In the present modification example, a dielectric member 630 is made of fluorine resin (for example, Teflon (registered trademark)), alumina (Al₂O₃), quartz or the like, and has a shape optimized for suppressing reflection of a microwave. In this way, while transmission loss of the microwave is suppressed and a phase of the microwave is synchronized at each branch point Dp, the microwave can be split uniformly and transmitted to each internal conductor 315a.

Since electric field strength at an end portion of the distribution waveguide 910 is weak, the microwave is not transmitted to a coaxial waveguide 315 efficiently if the internal conductor 315a is positioned in the vicinity of the end portion thereof. For this reason, a distance between the end portion of the distribution waveguide 910 (end portion of the space S) and a central axis of the internal conductor 315a is set to be about λg/4 if a wavelength in the distribution waveguide 910 is λg, such that the internal conductor 315a is positioned at a position of a peak of an electric field standing wave. Alternatively, the distance may not be about λg/4.

Instead of forming the space S within the cover body 300, the space S may also be formed by protruding the end portion of the distribution waveguide 910 toward the outer side of a processing chamber 100. Alternatively, as shown in FIG. 12 which is a cross-sectional view taken along line G-G of FIG. 11, the space S may be a plurality of grooves formed in the cover body 300 or may be one groove surrounding each internal conductor 315a. Further, a cross-sectional view taken along line X-X of FIG. 11 is FIG. 9, like the second embodiment.

In accordance with the plasma processing apparatus 10 of the modification example described above, by using the distribution waveguide 910 and the dielectric member 630, the microwave can be transmitted to the internal conductor 315a from the internal conductor 600a without using the branch plate 610. Moreover, by forming the space S within the cover body 300, the distribution waveguide 910 can be designed more compactly. As a result, an upper part of the processing chamber 100 can be designed more simply.

### Third Embodiment

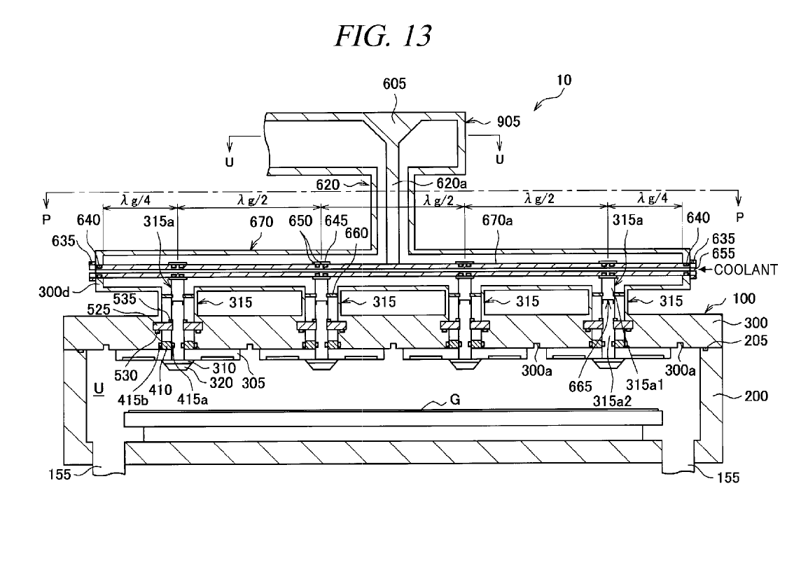

Hereinafter, a plasma processing apparatus 10 in accordance with a third embodiment will be explained with reference to FIGS. 13 to 15. The plasma processing apparatus 10 in accordance with the third embodiment is different from the plasma processing apparatus 10 in accordance with the first embodiment in that the former does not include the branch plate 610 (branch unit) of the latter; and the former has a different kind of a spring member. Other than these differences, both have almost the same configuration.

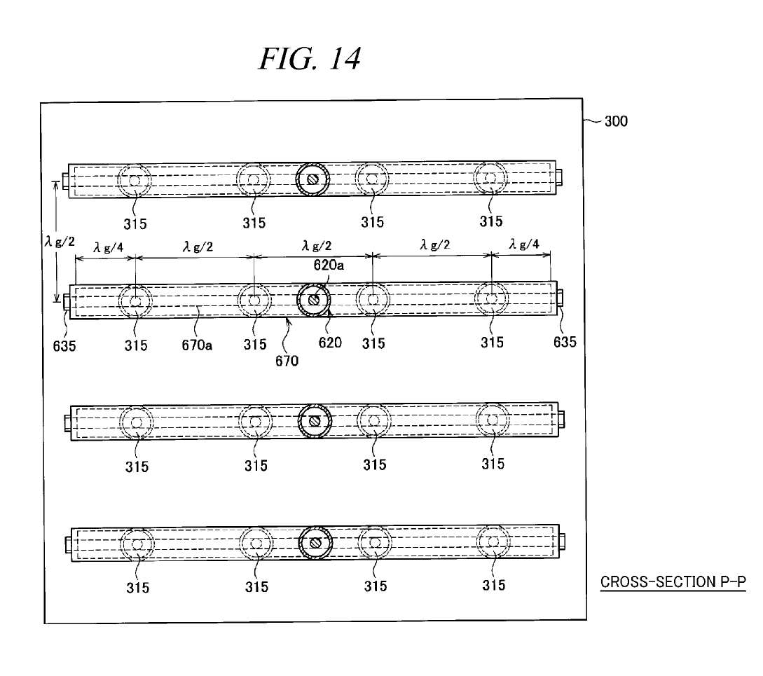

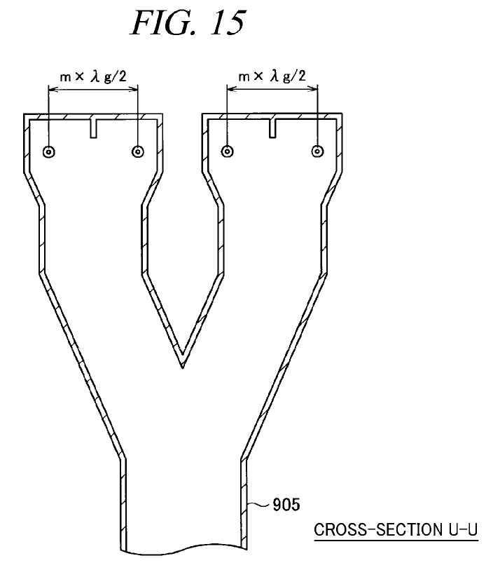

FIG. 14 is a cross-sectional view taken along line P-P of FIG. 13. As shown in FIGS. 13 and 14, in the present embodiment, a plurality of internal conductors 315a is connected directly with an internal conductor 670a of a branch coaxial waveguide 670 at a pitch of a half of a wavelength λg in the branch coaxial waveguide 670. Further, FIG. 15 is a cross-sectional view taken along line U-U of FIG. 13. A Y-branch of FIG. 15 is used in a branch waveguide 905.

Four internal conductors 315a are hung on the internal conductor 670a of the branch coaxial waveguide 670 at an interval of about n₁×λg/2 (here, n₁=1). In the present embodiment, a pitch between the branch coaxial waveguides 670 is set to be the same as a pitch between coaxial waveguides 315, so that a dielectric plate has the same size in column-wise and row-wise and a surface wave propagation mode has a good symmetry. Therefore, it becomes easy to obtain plasma uniformity in the dielectric plate surface.

A connector 665 that connects an upper internal conductor 315a1 and a lower internal conductor 315a2 is installed in the internal conductor 315a. Accordingly, while the upper internal conductor 315a1 is electrically connected with the lower internal conductor 315a2, the connector 665 absorbs thermal expansion or thermal contraction to prevent stress caused by the thermal expansion or the thermal contraction from being applied to the internal conductor 315a.

In accordance with the plasma processing apparatus of the third embodiment described above, by connecting four internal conductors 315a with the internal conductor 670a of the branch coaxial waveguide at the same interval on a straight line, a microwave can be transmitted from the internal conductor 670a of the branch coaxial waveguide to the internal conductors 315a without using the branch plate 610.

Further, a dielectric plate 305 is lifted up by using an O-ring 530 instead of the spring member used in the first embodiment. To be specific, a ring-shaped dielectric member 525 through which the internal conductor 315a passes is installed to fill a space between a cover member 300 and the internal conductor 315a, and the O-ring 530 for lifting up the internal conductor 315a is installed at a bottom portion of an outer periphery of the ring-shaped dielectric member 525. Further, installed at an upper portion of an inner periphery of the ring-shaped dielectric member 525 is a cushion ring 535 for absorbing a local stress applied to the internal conductor 315a when the internal conductor 315a is lifted up.

### Modification Example of the Third Embodiment

Further, there are modification examples 1 to 3 of the third embodiment as follows.

### Modification Example 1

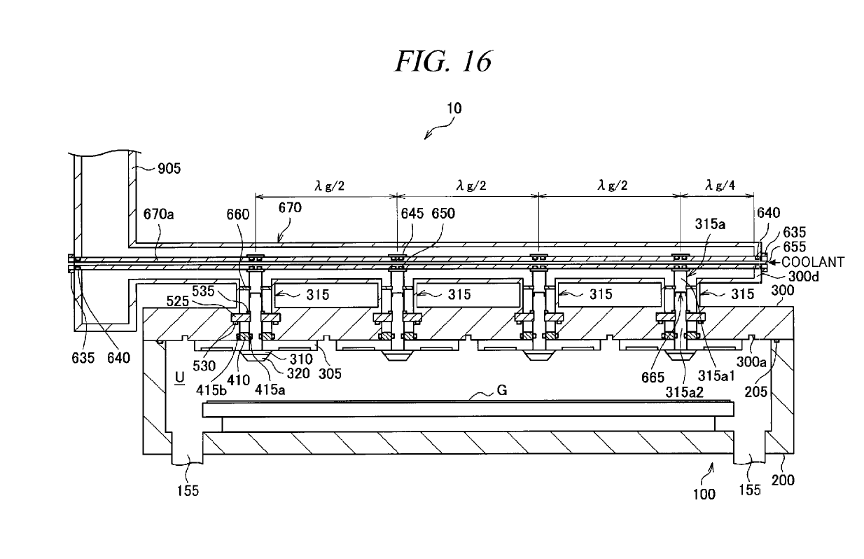

A plasma processing apparatus 10 in accordance with the modification example 1 of the third embodiment as illustrated in FIG. 16 is different from the third embodiment in the existence of a vertical coaxial waveguide and the installation direction of a branch waveguide. That is, in the present modification example, there is no vertical coaxial waveguide and a branch waveguide 905 is connected with an internal conductor 670a at an end portion of a branch coaxial waveguide 670.

In this case, a pitch between coaxial waveguides 315 is also maintained at about n₁×λg/2, and microwave power is uniformly split and provided to each coaxial waveguide 315.

### Modification Example 2

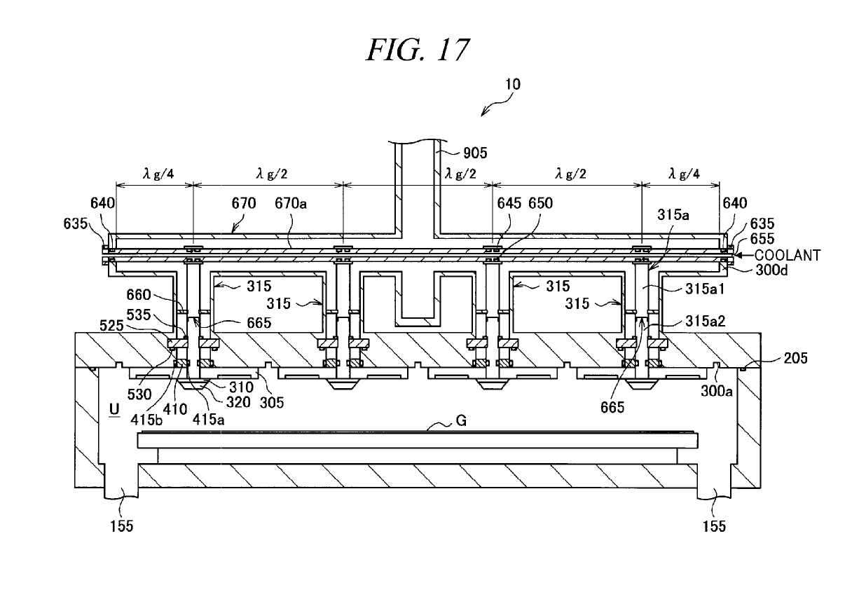

In a modification example 2 of the third embodiment as illustrated in FIG. 17, there are no vertical coaxial waveguides and a branch waveguide 905 is connected with an internal conductor 670a at a center portion of a branch coaxial waveguide 670.

In this case, a pitch between coaxial waveguides 315 is maintained at about n₁×λg/2. In the present modification example, a transmission line is designed such that synchronization of phases of microwaves and reflection at an end portion can be controlled well. Accordingly, the microwave can be transmitted to a plurality of dielectric plates 305 while power is uniformly split.

### Modification Example 3

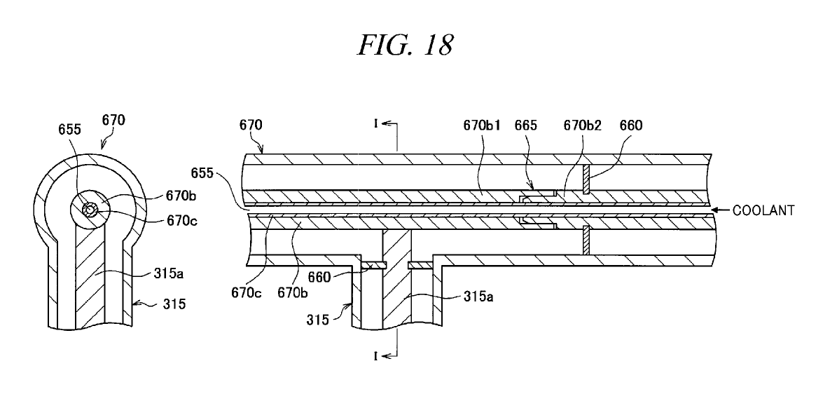

An enlarged view of a branch coaxial waveguide 670 of a modification example 3 of the third embodiment is illustrated on the right side of FIG. 18 and a cross-sectional view taken along line I-I of FIG. 18 is illustrated on the left side thereof. As shown in FIG. 18, an internal conductor of the branch coaxial waveguide 670 in accordance with the modification example 3 is made up of an outer pipe 670b and an internal pipe 670c. A path 655 for flowing coolant is installed within the internal pipe 670c. Further, a holding unit 660 is installed at the outer pipe 670b such that the internal conductor is positioned on a central axis of the branch coaxial waveguide 670.

The internal pipe 670c is installed to make contact with an inner periphery of the outer pipe 670b. The outer pipe 670b is separated into a plurality of pipes which is connected with each other by a connector 665. That is, by connecting a recessed portion of a pipe 670b1 of the outer pipe 670b with a protruded portion of a pipe 670b2 of the outer pipe 670b, the separated pipes are electrically connected with each other. Further, the connector 665 absorbs thermal expansion or thermal contraction to prevent stress caused by the thermal expansion or the thermal contraction from being applied to the pipes.

In accordance with the present modification example, since the pipe is formed in a double structure and the connector 665 is installed, the outer pipe 670b can slide in a horizontal direction without exerting an influence upon the internal pipe 670c and the stress, which is caused by the thermal expansion or the thermal contraction and applied to a transmission line, can be absorbed by the connector 665. Further, by allowing the coolant to flow in the internal pipe 670c, the internal conductor (pipe) can be efficiently cooled by heat conduction.

### Fourth Embodiment

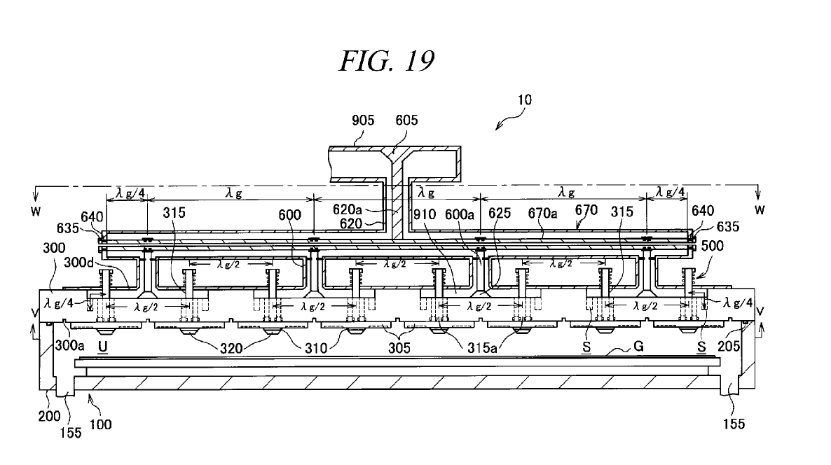

Hereinafter, a plasma processing apparatus 10 in accordance with a fourth embodiment will be explained with reference to FIGS. 19 to 21. The plasma processing apparatus 10 in accordance with the fourth embodiment is different from that of the first embodiment in that the former uses a distribution waveguide 910 as a branch unit instead of using the branch plate 610 of the first embodiment.

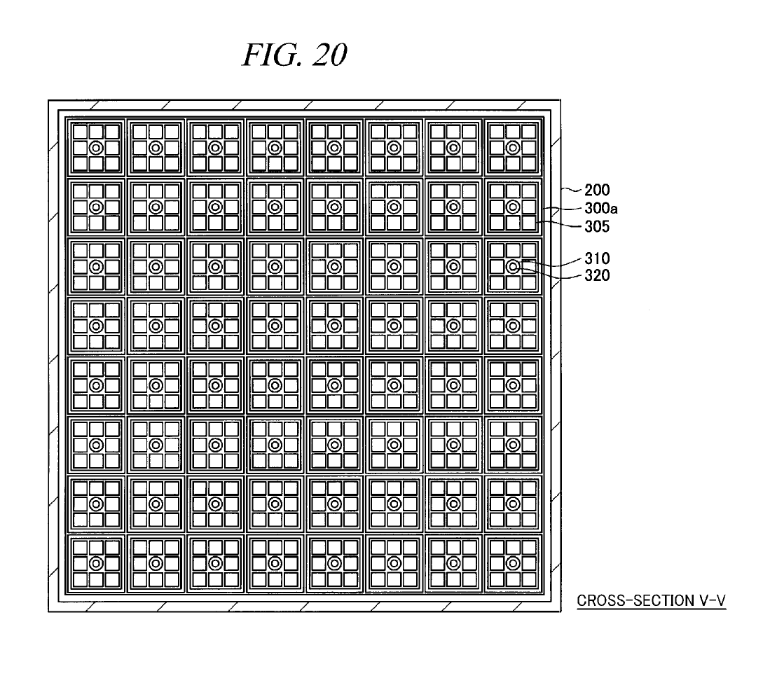

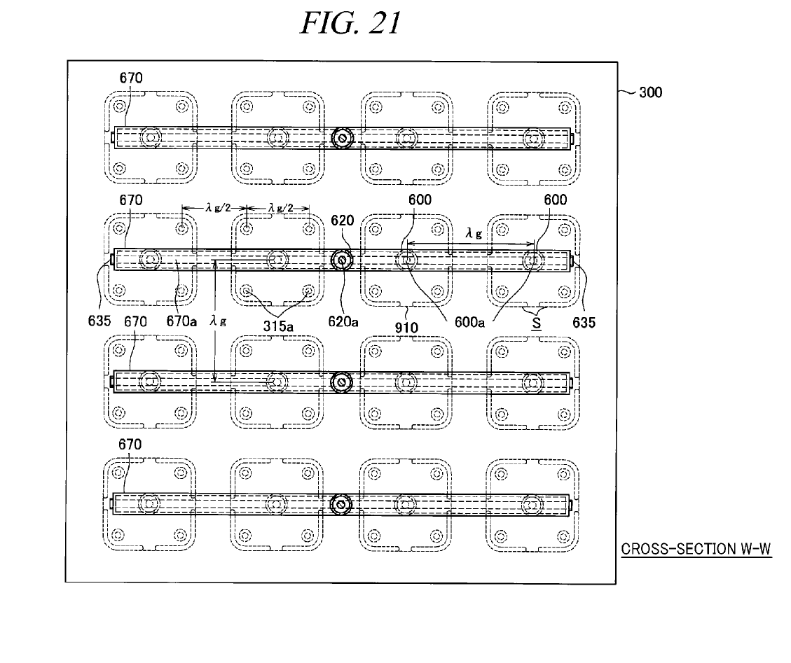

In the plasma processing apparatus 10 in accordance with the present embodiment, as shown in FIG. 20 which is a cross-sectional view taken along line V-V of FIG. 19, each dielectric plate 305 has a good symmetry, so that it becomes easy to generate uniform plasma within one sheet of the dielectric plate 305. Further, with reference to FIG. 21 which is a cross-sectional view taken along line W-W of FIG. 19, the plurality of dielectric plates 305 is arranged at the same interval of an integer multiple of λg/2, so that it is possible to generate uniform plasma when a microwave is introduced by using an internal conductor 315a of the coaxial waveguide.

Furthermore, a branch coaxial waveguide 670 in accordance with the present embodiment is an example of a third coaxial waveguide positioned substantially parallel to the plurality of dielectric plates 305. A transmission line includes plural third coaxial waveguides and further includes a plurality of fourth coaxial waveguides. Each internal conductor of the fourth coaxial waveguides is connected with each internal conductor of the third coaxial waveguides and positioned above each internal conductor of a plurality of first coaxial waveguides. Further, the internal conductors of the plurality of fourth coaxial waveguides may be arranged at an interval of about n₂×λg/2, and n₂ is an integer equal to or greater than 1.

In this way, it is possible to form a transmission line branched in multiple levels using coaxial waveguides or a waveguide(s) and a coaxial waveguide(s). Accordingly, a microwave can be transmitted uniformly to 64 sheets of the dielectric plates 305.

In accordance with the present embodiment, the microwave can be uniformly supplied into a processing space U from the plurality of dielectric plates 305 arranged uniformly on the entire ceiling surface of a processing chamber 100 and thus uniform plasma can be generated.

In accordance with each embodiment described above, the upper part of the processing chamber 100 can be designed simply. Further, various plasma processes can be performed by using a low frequency microwave.

Moreover, it is desirable that n₁ and n₂ is 1 or 2. The reason for this is that if the value of n₁ or n₂ becomes larger, the travelling distance of the microwave becomes long, so that the synchronization of phases and the distribution of power become non-uniform, and thus it becomes difficult to uniformly split and transmit the microwave. Further, the reason for this is that if the value of n₁ or n₂ becomes larger, the transmission line becomes complicated and larger, so that it becomes difficult to perform the maintenance operation. Furthermore, if the value of n₁ or n₂ is 1, the distance between the internal conductors of the second coaxial waveguides is about λg/2. In this case, it is better to supply a low frequency microwave than a high frequency microwave. If the high frequency microwave is supplied, the waveguide wavelength λg of the microwave becomes short, so that the distance between the internal conductors of the second coaxial waveguides becomes short. Therefore, the number of the dielectric plates increases, and thus the cost increases.

Further, in each embodiment described above, it is desirable that the internal conductor of each coaxial waveguide is made of copper having thermal conductivity and electrical conductivity. Accordingly, heat applied to the internal conductor of the coaxial waveguide from the microwave or the plasma can be transferred efficiently, and also the microwave can be transmitted well.

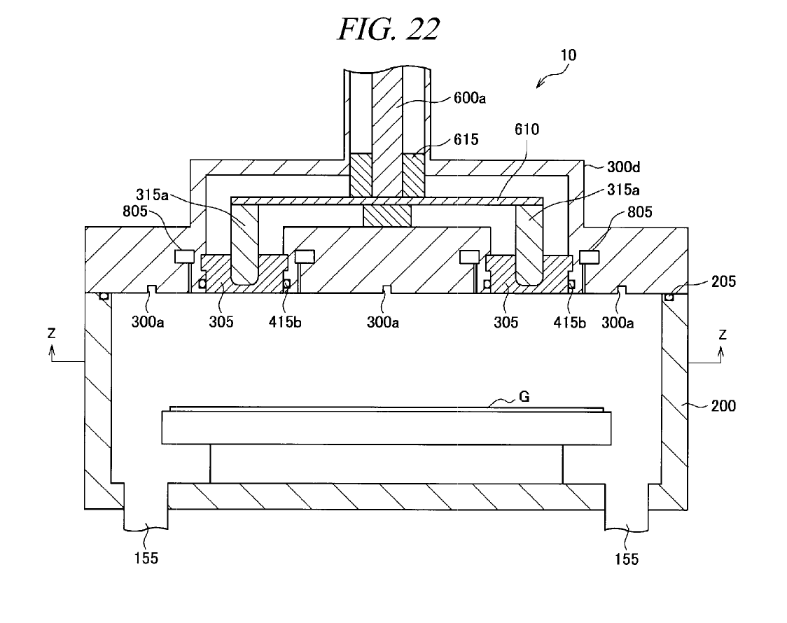

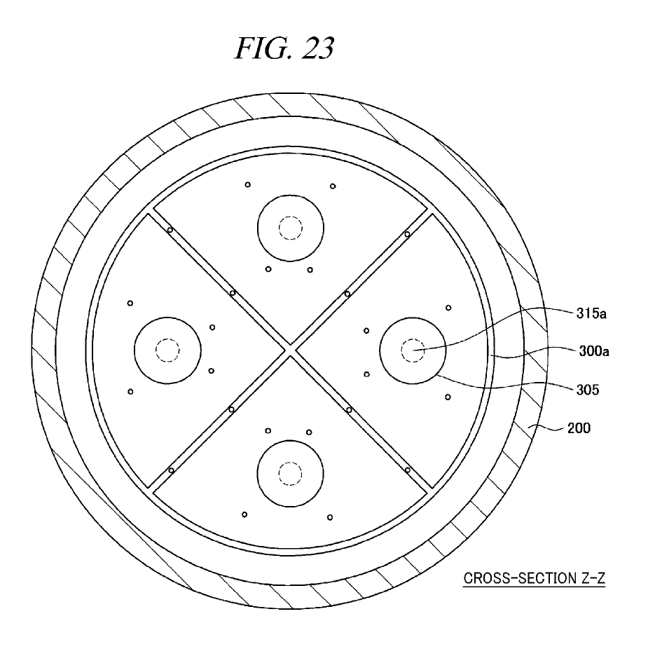

Furthermore, as described above, the internal conductor 315a is adjacent to or close to the plurality of dielectric plates 305 and is an example of a conductive rod that transmits the microwave to the plurality of dielectric plates 305. Here, the conductive rod may be electromagnetically or mechanically connected with the dielectric plates 305. Moreover, the conductive rod may be adjacent to the plurality of dielectric plates 305 as illustrated in FIG. 22 (FIG. 23 is a cross-sectional view taken along line Z-Z of FIG. 22). Further, although not shown, the conductive rod may be close to the plurality of dielectric plates 305 and electromagnetically connected thereto but not mechanically connected thereto. Furthermore, the conductive rod may have a plate shape or a tapered shape.

In particular, a non-controlled gap generated by mechanical difference or thermal expansion deteriorates an electric property of the apparatus. However, in case that a controlled gap is formed between the conductive rod and the dielectric plate 305 by positioning the conductive rod close to the dielectric plate 305, the microwave can be transmitted efficiently to the dielectric plate 305 without changing the electric property of the apparatus.

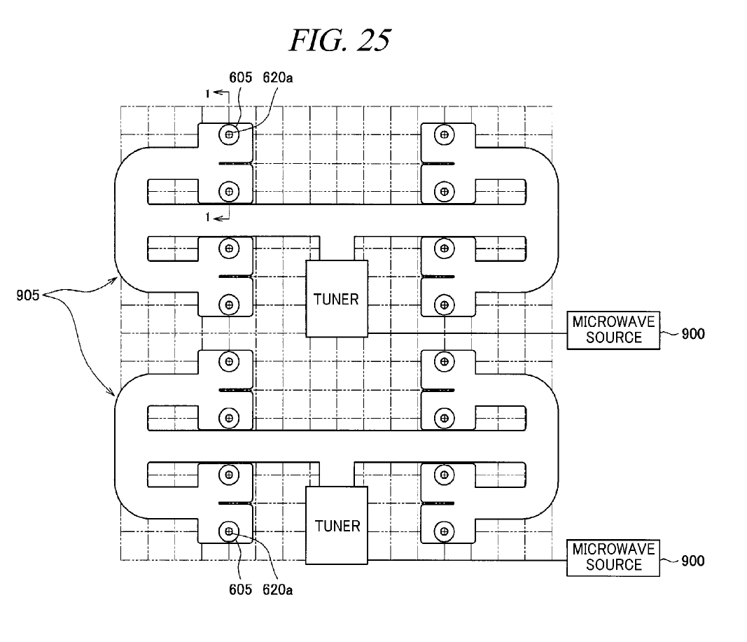

FIG. 25 illustrates a modification example of a branch waveguide 905. The branch waveguide 905 in accordance with the modification example is configured to have 2×2×2 branches of a tournament structure in a plane shape. The waveguide is branched symmetrically with respect to two sides of a microwave source 900. Since the branch waveguide is configured in the plane shape, it has a thin thickness (a length in a vertical direction of the paper surface of FIG. 25), so that it can be easily installed on the apparatus.

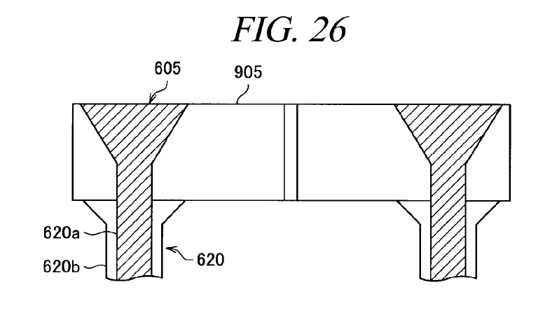

FIG. 26 is a cross-sectional view taken along line 1-1 of FIG. 25. In the branch waveguide 905 of the present modification example, when coaxial waveguides 620 are connected with the branch waveguide 905 via eight coaxial waveguide converters 605, a portion where the branch waveguide 905 is connected with an internal conductor 620a of the coaxial waveguide 620 is configured to have a tapered shape and also a portion where the branch waveguide 905 is connected with an outer conductor 620b is also configured to have a tapered shape, such that reflection of the microwave is suppressed.

In the above-described embodiments, the operations of the respective parts are interrelated and can be substituted with a series of operations in consideration of such an interrelation. Further, by such a substitution, the embodiments of the plasma processing apparatus can be used as embodiments of a method for operating the plasma processing apparatus or a method for cleaning the plasma processing apparatus.

(Frequency Limitation)

A microwave having a frequency of about 1 GHz or less is outputted from the microwave source 900 by using the plasma processing apparatus 10 in accordance with each embodiment, so that a good plasma processing can be achieved. A reason for this will be explained below.

In a plasma CVD process that deposits a thin film on a surface of a substrate by a chemical reaction, the film is adhered on an inner surface of a processing chamber as well as the surface of the substrate. If the film adhered on the inner surface of the processing chamber is peeled off and then adhered on the substrate, the yield is decreased. Further, an impurity gas generated from the film adhered on the inner surface of the processing chamber may be absorbed to the thin film, thereby deteriorating the film quality. Therefore, the inner surface of the chamber should be cleaned regularly in order to perform a high-quality process.

F radicals are often used for cleaning a silicon oxide film or a silicon nitride film. The F radicals etch these films at a high speed. The F radicals are generated by exciting plasma with F containing gases such as NF₃ or SF₆ and decomposing gas molecules. If the plasma is excited by using a mixed gas containing F and O, F or O recombines with electrons in the plasma, so that an electron density in the plasma is reduced. In particular, if the plasma is excited by using a gas containing F having the highest electronegativity among all materials, the electron density is remarkably reduced.

In order to demonstrate this, the inventor measured an electron density of plasma after generating plasma under a condition of a microwave frequency of about 2.45 GHz, a microwave power density of about 1.6 W/cm⁻² and a pressure of about 13.3 Pa. As a result, in case of using an Ar gas, an electron density was about 2.3×10¹² cm⁻³, whereas in case of using a NF₃ gas, an electron density was about 6.3×10¹⁰ cm⁻³ which is smaller by one digit place or more as compared to the case of using an Ar gas.

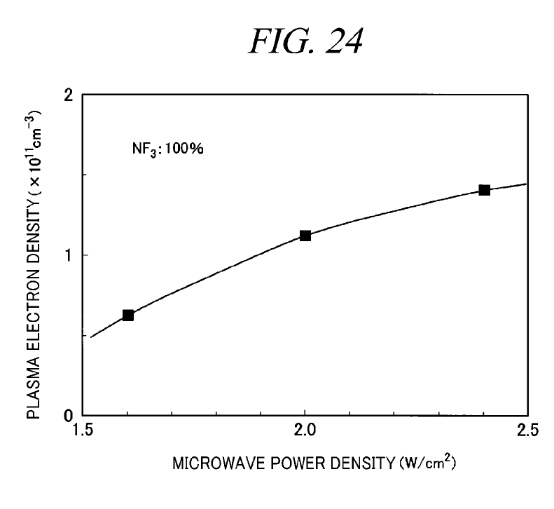

As illustrated in FIG. 24, if a microwave power density increases, an electron density of plasma increases. To be specific, if the power density increases from about 1.6 W/cm² to about 2.4 W/cm², the electron density of the plasma increases from about 6.3×10¹⁰ cm⁻³ to about 1.4×10¹¹ cm⁻³.

Meanwhile, if a microwave of about 2.5 W/cm or more is applied, there is a high risk that a dielectric plate may be heated and cracked or abnormal electric discharge may occur in each part, thereby becoming uneconomical. Therefore, it is practically difficult to provide an electron density of about 1.4×10¹¹ cm⁻³ or more by using the NF₃ gas. That is, in order to generate uniform and stable plasma by using the NF₃ gas having a very low electron density, a surface wave resonance density nₛ should be about 1.4×10¹¹ cm⁻³ or less.

The surface wave resonance density nₛ represents the lowest electron density at which a surface wave can propagate between the dielectric plate and the plasma. If the electron density is lower than the surface wave resonance density nₛ, the surface wave does not propagate and thus extremely non-uniform plasma is excited. As represented by Formula (2), the surface wave resonance density nₛ is proportional to a cut-off density n_{c} represented by Formula (1).

n_{c}=ε₀mₑω²/e₂ (1)

nₛn_{c}(1+εᵣ) (2)

Here, ε₀ is vacuum permittivity, mₑ is mass of an electron, ω is a microwave angular frequency, e is an elementary electric charge, and εᵣ is a dielectric constant of a dielectric plate.

As can be seen from Formulas (1) and (2), the surface wave resonance density nₛ is proportional to the square of the microwave frequency. Therefore, a low frequency may be selected to propagate the surface wave at a lower electron density and thus to obtain uniform plasma. For example, if the microwave frequency is reduced to ½, uniform plasma can be obtained even with ¼ of the electron density. Accordingly, such a reduction in the microwave frequency is very efficient to enlarge a process window.

At a frequency of about 1 GHz, the surface wave resonance density nₛ becomes equal to a practical electron density of about 1.4×10¹¹ cm⁻³ when using the NF₃ gas. That is, if a microwave frequency of about 1 GHz or less is selected, it is possible to excite uniform plasma having a practical power density by using any gas.

From the above, a microwave having a frequency of about 1 GHz or less is outputted from the microwave source 900; the microwave outputted from the microwave source 900 is transmitted to the transmission line (e.g., the coaxial waveguide 600); the microwave transmitted through the transmission line is split into a plurality of microwaves by the branch unit (e.g., the branch plate 610 or the distribution waveguide 910) and then transmitted to the plurality of conductive rods; the microwave is emitted from one or more conductive rods adjacent to or close to each dielectric plate into the processing chamber via each dielectric plate; a processing gas introduced into the processing chamber is excited by the emitted microwave; and thus a good plasma processing can be performed on the target object (e.g., the substrate G).

In particular, for example, a microwave having a frequency of about 1 GHz or less is outputted from the microwave source 900 of the plasma processing apparatus 10 in accordance with each embodiment; the microwave outputted from the microwave source 900 is transmitted to the transmission line; the microwave transmitted through the transmission line is split into a plurality of microwaves by the branch unit and then transmitted to the plurality of conductive rods; the microwave is emitted from one or more conductive rods adjacent to or close to each dielectric plate into the processing chamber via each dielectric plate; a cleaning gas introduced into the processing chamber is excited by the emitted microwave; and thus the plasma processing apparatus can be cleaned well only by using a single gas.

Further, a power supply apparatus capable of supplying a microwave having a frequency of about 1 GHz or less to the plasma processing apparatus, a power supply apparatus capable of supplying a microwave having a frequency of about 1 GHz or less to the plasma processing apparatus through the transmission line of the plasma processing apparatus 10 in accordance with each embodiment may be configured to include: a microwave source that outputs a microwave; a transmission line that transmits the microwave outputted from the microwave source; a plurality of conductive rods, adjacent to or close to a plurality of dielectric plates installed at an inner wall of a processing chamber, configured to transmit the microwave to the plurality of dielectric plates; and a branch unit that splits the microwave transmitted through the transmission line into a plurality of microwaves and transmits them to the plurality of conductive rods, wherein one or more conductive rods are adjacent to or close to each dielectric plate.

Further, in the above-described embodiments, the microwave source 900 outputting a microwave of about 915 MHz is used, but the microwave source outputting a microwave of about 896 MHz, 922 MHz or 2.45 GHz may be used. Further, the microwave source corresponds to an electromagnetic wave source outputting an electromagnetic wave for exciting plasma.

As described above, the embodiments of the present invention have been explained with reference to the accompanying drawings, but the present invention is not limited thereto. It is clear that various changes and modifications can be made by those skilled in the art within the scope of the claims, and it shall be understood that all changes and modifications are included in the scope of the present invention.

For example, the plasma processing apparatus in accordance with the present invention is not limited to the above-described embodiments. For example, adjacent coaxial waveguides among parallel coaxial waveguides and vertical coaxial waveguides may be connected to each other with a regularity of an interval of about n×λg/2 (n is an integer equal to or greater than 1), and end portions may be terminated with a regularity of λg/4. In this way, a transmission line having multilevel-branches in free manner can be configured to transmit a microwave uniformly without loss.

Further, the plasmas processing apparatus in accordance with the present invention may process, e.g., a large-sized glass substrate, a circular silicon wafer or a square silicon-on-insulator (SOI).

Further, the plasma processing apparatus in accordance with the present invention may perform various plasma processes such as a film forming process, a diffusion process, an etching process and an asking process.

1. A plasma processing apparatus that performs a plasma processing on a target object by exciting a gas by an electromagnetic wave, the apparatus comprising:
a processing chamber;
an electromagnetic wave source configured to output the electromagnetic wave;
a transmission line configured to transmit the electromagnetic wave outputted from the electromagnetic wave source;
a plurality of dielectric plates installed on an inner wall of the processing chamber and configured to allow the electromagnetic wave to pass therethrough and to be emitted to an inside of the processing chamber;
a plurality of conductive rods positioned adjacent to or close to the plurality of dielectric plates and configured to transmit the electromagnetic wave to the plurality of dielectric plates; and
a branch unit configured to split the electromagnetic wave transmitted through the transmission line into a plurality of electromagnetic waves and transmit them to the plurality of conductive rods,
wherein one or more conductive rods are adjacent to or close to each of the dielectric plates.

2. The plasma processing apparatus of claim 1, wherein the transmission line includes a first coaxial waveguide, and
the branch unit is a branch member configured to connect an internal conductor of the first coaxial waveguide with each of the conductive rods.

3. The plasma processing apparatus of claim 1, wherein the transmission line includes a first coaxial waveguide, and
the branch unit is a distribution waveguide into which an internal conductor of the first coaxial waveguide and the plurality of conductive rods are inserted.

4. The plasma processing apparatus of claim 2, wherein the plurality of conductive rods is concentrically arranged with respect to a central axis of the internal conductor of the first coaxial waveguide at the same interval while being substantially parallel to each other.

5. The plasma processing apparatus of claim 2, wherein the plurality of conductive rods is arranged in a point symmetry with respect to a central axis of the internal conductor of the first coaxial waveguide while being substantially parallel to each other.

6. The plasma processing apparatus of claim 1, wherein the branch unit is installed to be substantially parallel to the plurality of dielectric plates and the branch unit is an internal conductor of a second coaxial waveguide connecting the transmission line with the plurality of conductive rods.

7. The plasma processing apparatus of claim 6, wherein the transmission line is a first coaxial waveguide or a waveguide.

8. The plasma processing apparatus of claim 6, wherein the plurality of conductive rods is connected to the internal conductor of the second coaxial waveguide at the same interval while being substantially parallel to each other.

9. The plasma processing apparatus of claim 6, wherein a pitch between the dielectric plates is set to be about n₁×λg/2, λg being a waveguide wavelength of the electromagnetic wave transmitted through the second coaxial waveguide and n₁ being an integer equal to or greater than 1.

10. The plasma processing apparatus of claim 2, further comprising:
a short-circuit unit configured to short-circuit a cover of the processing chamber and each of the conductive rods,
wherein a distance from a position where the branch member is connected with each of the conductive rods to the short-circuit unit is set to be about λg/4, λg being a wavelength of the electromagnetic wave transmitted through each of the conductive rods.

11. The plasma processing apparatus of claim 6, further comprising:
a short-circuit unit configured to short-circuit a cover of the processing chamber and each of the conductive rods,
wherein a distance from a position where the internal conductor of the second coaxial waveguide is connected with each of the conductive rods to the short-circuit unit is set to be about λg/4, λg being a wavelength of the electromagnetic wave transmitted through each of the conductive rods.

12. The plasma processing apparatus of claim 3, further comprising:
a short-circuit unit configured to short-circuit a cover of the processing chamber and each of the conductive rods,
wherein an end portion of the cover of the processing chamber includes one of an end portion of the distribution waveguide in a lengthwise direction thereof and end portions formed in an L-shape at both ends of the distribution waveguide; and
a distance from each of the conductive rods to the end portion of the cover of the processing chamber is set to be about λg/4, λg being a waveguide wavelength of the electromagnetic wave transmitted through the distribution waveguide.

13. The plasma processing apparatus of claim 6, further comprising:
a short-circuit unit configured to short-circuit a cover of the processing chamber and the internal conductor of the second coaxial waveguide,
wherein a distance from a position where the internal conductor of the second coaxial waveguide is connected with each of the conductive rods to the short-circuit unit is set to be about λg/4, λg being a waveguide wavelength of the electromagnetic wave transmitted through the second coaxial waveguide.

14. The plasma processing apparatus of claim 2, wherein a dielectric member for impedance matching is installed in a branch point of the branch unit.

15. The plasma processing apparatus of claim 1, wherein the transmission line includes a plurality of first coaxial waveguides,
each of the plurality of first coaxial waveguides is configured to transmit the electromagnetic wave to the plurality of the conductive rods via the branch unit,
the transmission line further includes at least one third coaxial waveguide positioned substantially parallel to the plurality of dielectric plates, and
internal conductors of the plurality of first coaxial waveguides are connected with an internal conductor of the third coaxial waveguide.

16. The plasma processing apparatus of claim 15, wherein the internal conductors of the plurality of first coaxial waveguides connected with the internal conductor of the third coaxial waveguide are arranged at an interval of about n₂×λg/2, λg being a waveguide wavelength of the electromagnetic wave transmitted through the third coaxial waveguide and n₂ being an integer equal to or greater than 1.

17. The plasma processing apparatus of claim 15, wherein the transmission line includes a plurality of the third coaxial waveguides and further includes a plurality of fourth coaxial waveguides,
each internal conductor of the fourth coaxial waveguides is connected with each internal conductor of the third coaxial waveguides, and
the internal conductors of the plurality of fourth coaxial waveguides are positioned above the internal conductors of the plurality of the first coaxial waveguides, and arranged at an interval of about n₂×λg/2, n₂ being an integer equal to or greater than 1.

18. The plasma processing apparatus of claim 1, wherein the electromagnetic wave source is connected with a branch waveguide having a tournament structure in which a two-branch is repeated one time or more.

19. The plasma processing apparatus of claim 18, wherein a branch point of the branch waveguide has a T-branch or a Y-branch structure.

20. The plasma processing apparatus of claim 18, wherein the branch waveguide has the same distance from a connection point with the electromagnetic wave source to each branch end point of the branch waveguide.

21. The plasma processing apparatus of claim 9, wherein the integer n₁ is 1 or 2.

22. The plasma processing apparatus of claim 6, wherein a coolant flow path is installed within the internal conductor of the second coaxial waveguide.

23. The plasma processing apparatus of claim 15, wherein a coolant flow path is installed within the internal conductor of the third coaxial waveguide.

24. The plasma processing apparatus of claim 22, wherein the internal conductor of the second coaxial waveguide is made up of an outer pipe and an inner pipe.

25. The plasma processing apparatus of claim 24, wherein a coolant is flowed through an inside of the internal pipe.

26. The plasma processing apparatus of claim 6, wherein the internal conductor of the second coaxial waveguide is divided into two or more internal conductors, and
the divided two or more internal conductors of the second coaxial waveguide are connected with each other by a connector.

27. The plasma processing apparatus of claim 26, wherein the connector is installed at an outer pipe of the internal conductor of the second coaxial waveguide.

28. The plasma processing apparatus of claim 26, wherein a holding unit configured to hold the internal conductor of the second coaxial waveguide is installed in the vicinity of the connector.

29. The plasma processing apparatus of claim 6, wherein the plurality of conductive rods is slidably engaged with the internal conductor of the second coaxial waveguide at a connection point therebetween in a lengthwise direction of the second coaxial waveguide.

30. The plasma processing apparatus of claim 10, wherein the plurality of conductive rods is slidably engaged with the cover of the processing chamber at the short-circuit unit.

31. The plasma processing apparatus of claim 1, wherein the electromagnetic wave source outputs an electromagnetic wave having a frequency of about 1 GHz or less.

32. A power supply apparatus capable of supplying an electromagnetic wave having a frequency of about 1 GHz or less to a plasma processing apparatus, the power supply apparatus comprising:
an electromagnetic wave source configured to output the electromagnetic wave;
a transmission line configured to transmit the electromagnetic wave outputted from the electromagnetic wave source;
a plurality of conductive rods, positioned adjacent to or close to a plurality of dielectric plates installed on an inner wall of the processing chamber, configured to transmit the electromagnetic wave to the plurality of dielectric plates; and
a branch unit configured to split the electromagnetic wave transmitted through the transmission line into a plurality of electromagnetic waves and transmit them to the plurality of the conductive rods,
wherein one or more conductive rods are adjacent to or close to each of the dielectric plates.

33. A method for operating a plasma processing apparatus, the method comprising:
outputting an electromagnetic wave having a frequency of about 1 GHz or less from an electromagnetic wave source;
transmitting the electromagnetic wave outputted from the electromagnetic wave source to a transmission line;
splitting the electromagnetic wave transmitted through the transmission line into a plurality of electromagnetic waves and transmitting them to a plurality of conductive rods;
emitting the electromagnetic wave into a processing chamber from one or more conductive rods adjacent to or close to each of dielectric plates via each of the dielectric plates; and
performing a desired plasma processing on a target object by exciting a processing gas introduced into the processing chamber by the emitted electromagnetic wave.

34. A method for cleaning a plasma processing apparatus, the method comprising:
outputting an electromagnetic wave having a frequency of about 1 GHz or less from an electromagnetic wave source;
transmitting the electromagnetic wave outputted from the electromagnetic wave source to a transmission line;
splitting the electromagnetic wave transmitted through the transmission line into a plurality of electromagnetic waves and transmitting them to a plurality of conductive rods;
emitting the electromagnetic wave into a processing chamber from one or more conductive rods adjacent to or close to each of dielectric plates via each of the dielectric plates; and
cleaning the plasma processing apparatus by exciting a cleaning gas introduced into the processing chamber by the emitted electromagnetic wave.
